(19) United States
(12) Patent Application Publication
(10) Pub. No.: US 2025/0035827 A1
(43) Pub. Date: Jan. 30, 2025

(54) WAVELENGTH SELECTIVE ABSORPTION FILTER AND ORGANIC ELECTROLUMINESCENT DISPLAY DEVICE

(71) Applicant: FUJIFILM Corporation, Tokyo (JP)

(72) Inventors: Kunihiro ATSUMI, Kanagawa (JP); Nobutaka FUKAGAWA, Kanagawa (JP)

(73) Assignee: FUJIFILM Corporation, Tokyo (JP)

(21) Appl. No.: 18/901,999

(22) Filed: Sep. 30, 2024

Related U.S. Application Data
(63) Continuation of application No. PCT/JP2023/018136, filed on May 15, 2023.

(30) Foreign Application Priority Data
May 24, 2022 (JP) 2022-084869
Nov. 7, 2022 (JP) 2022-178289

(51) Int. Cl. G02B 5/22; H10K 59/80

(52) U.S. Cl. CPC G02B 5/223; H10K 59/8791

(57) ABSTRACT

A wavelength selective absorption filter and an organic electroluminescent display device including the wavelength selective absorption filter, which includes a resin, and dyes B, C, and D having a main absorption wavelength range in different wavelength regions, in which a light absorbance Ab (λ) of the wavelength selective absorption filter at a wavelength of λ nm satisfies Relational Expression (I) Ab (500)/Ab (600)<0.7 and Relational Expression (II) Ab (430)/Ab (700)<3.0.

### CROSS-REFERENCE TO RELATED APPLICATIONS

This application is a Continuation of PCT International Application No. PCT/JP2023/018136 filed on May 15, 2023, which was published under PCT Article 21(2) in Japanese, and which claims priority under 35 U.S.C. § 119 (a) to Japanese Patent Application No. 2022-084869 filed in Japan on May 24, 2022, and Japanese Patent Application No. 2022-178289 filed in Japan on Nov. 7, 2022. Each of the above applications is hereby expressly incorporated by reference, in its entirety, into the present application.

### BACKGROUND OF THE INVENTION

### 1. Field of the Invention

The present invention relates to a wavelength selective absorption filter and an organic electroluminescent display device.

### 2. Description of the Related Art

An organic electroluminescent (OLED) display device is a device that displays an image by utilizing self-luminescence of an OLED element. Therefore, the OLED display device has advantages that a high contrast ratio, a high color reproducibility, a wide viewing angle, high-speed responsiveness, and a reduction in thickness and weight can be achieved, as compared with various display devices such as a liquid crystal display device and a plasma display device. In addition to these advantages, in terms of flexibility, research and development are being actively carried out as a next-generation display device.

On the other hand, in a case where the OLED display device is used in an external light environment such as outdoors, external light is reflected by a metal electrode or the like configuring the OLED display device, resulting in a display defect such as a decrease in contrast. A technique of suppressing external light reflection by providing a circularly polarizing plate comprising an optically anisotropic layer such as a λ/4 retardation film is known, but the technique causes a problem in that brightness decreases.

In recent years, a technique of suppressing a decrease in brightness while suppressing external light reflection by providing a light absorbing layer capable of absorbing external light has been studied.

For example, JP2017-203810A describes a light absorbing layer containing a carbon black pigment and a dye (coloring agent), having a transmittance of 15% to 50% in a wavelength range of 400 nm to 700 nm, and having a haze value of 1.0 or less, as a light absorbing layer, which is provided between a light emitting layer and antireflection film, in a white light source type of an OLED color filter.

In addition, JP2014-132522A describes a light absorption filter showing an absorption spectrum having a negative correlation with an emission spectrum obtained by synthesizing spectra for each pixel of a plurality of colors, as a light absorption filter in an OLED display device.

In WO2021/014973A, as a wavelength selective absorption filter in an OLED display device, a wavelength selective absorption filter containing four kinds of dyes each having absorption at different wavelengths such that a specific relationship of light absorbance is satisfied.

### SUMMARY OF THE INVENTION

On the other hand, in suppression of external light reflection, not only a magnitude of an external light reflectivity but also suppression of an influence of a tint of the external light reflection on an original tint of an image display apparatus is required.

As described in WO2021/014973A, in the light absorption layer (light absorption filter) as described in JP2017-203810A, a tint of an image of an OLED display device is changed by a coloring material such as a coloring agent contained in the light absorption filter, so that it was found that there is room for improvement in suppressing the change in tint. Further, the light absorption filter described in JP2014-132522A has no description of how to realize a target absorption spectrum.

In addition, as a result of repeated studies by the present inventors, in WO2021/014973A, although both the external light reflection and the brightness decrease are suppressed at a certain level by the wavelength selective absorption filter, and the change in tint due to the presence or absence of the wavelength selective absorption filter can be suppressed, suppression of the influence of the tint of the external light reflection on the original tint of the image display apparatus is not described.

Further, although a development of a display device having a wider color gamut and a higher chroma saturation than those in the related art is in progress, it has been found that in a case where the wavelength selective absorption filter described in WO2021/014973A is used in a display device having a wide color gamut and a high chroma saturation, there is room for improvement in suppressing a decrease in brightness.

Therefore, an object of the present invention is to provide a wavelength selective absorption filter that achieves both suppression of external light reflection and suppression (that is, a difference in tint between display light and reflected light of a display image is hardly visually recognized) of an influence of a reflected tint on an original tint of the display image, in which the suppression of a decrease in brightness of light emitted from an OLED is excellent in a case of being applied to a wide color gamut OLED display device, and is to provide an organic electroluminescent display device including the same.

As a result of diligent studies conducted by the present inventors in view of the object, it was found that both the suppression of external light reflection and the suppression of the influence of reflected tint on the original tint of a display image can be achieved by a wavelength selective absorption filter in which a content ratio of a dye having a main absorption wavelength range in a wavelength range of 580 to 620 nm is increased, and the brightness decrease can be minimized by combining this wavelength selective absorption filter and a light source having a narrow half-width of emitted light in G (green). Further studies have been carried out based on these findings, whereby the present invention has been completed.

That is, the above object has been achieved by the following means.

<1>

A wavelength selective absorption filter including a resin, and the following dyes B, C, and D having a main absorption wavelength range in different wavelength regions, in which a light absorbance Ab (λ) of the wavelength selective absorption filter at a wavelength of λ nm satisfies Relational Expressions (I) and (II),
dye B: a dye having a main absorption wavelength range at a wavelength of 480 to 520 nm in the wavelength selective absorption filter,
dye C: a dye having a main absorption wavelength range at a wavelength of 580 to 620 nm in the wavelength selective absorption filter,
dye D: a dye having a main absorption wavelength range at a wavelength of 680 to 780 nm in the wavelength selective absorption filter,

Ab(500)/Ab(600)<0.7, and Relational Expression (I)

Ab(430)/Ab(700)<3.0. Relational Expression (II)

<2>

The wavelength selective absorption filter according to <1>, further including the following dye A,
dye A: a dye having a main absorption wavelength range at a wavelength of 390 to 435 nm in the wavelength selective absorption filter.

<3>

The wavelength selective absorption filter according to <1> or <2>, in which Relational Expression (II-a) is satisfied,

Ab(430)/Ab(700)<1.0. Relational Expression (II-a)

<4>

The wavelength selective absorption filter according to any one of <1> to <3>, in which Relational Expressions (III) and (IV) are satisfied,

Ab(430)/Ab(600)<1.0, and Relational Expression (III)

Ab(700)/Ab(600)<2.0. Relational Expression (IV)

<5>

The wavelength selective absorption filter according to any one of <1> to <4>, in which in a case where the wavelength selective absorption filter is not provided, the wavelength selective absorption filter is used in an organic electroluminescent display device in which a half-width of emitted light having a peak at a wavelength of 500 to 560 nm is 45 nm or less.

<6>

An organic electroluminescent display device in which in a case where a wavelength selective absorption filter is not provided, a half-width of emitted light having a peak at a wavelength of 500 to 560 nm is 45 nm or less, the organic electroluminescent display device including the wavelength selective absorption filter according to any one of <1> to <5>.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents and the like. In addition, in a case where a plurality of substituents and the like are close to each other (particularly in a case where the substituents and the like are adjacent to each other), unless otherwise specified, the substituents and the like may also be linked to each other to form a ring. In addition, unless otherwise specified, rings, for example, alicyclic rings, aromatic rings, and heterocyclic rings may be further condensed together and thus form a fused ring.

In the present invention, unless otherwise specified, one type of a component (such as a dye, a resin, and other components) forming the wavelength selective absorption filter may be contained in the wavelength selective absorption filter, and two or more types thereof may be contained.

In the present invention, in a case where a molecule has an E-type double bond and a Z-type double bond, the molecule may be either an E isomer or a Z isomer, or may be a mixture thereof unless otherwise specified.

In the present invention, the representation of a compound (including a complex) is used to have a meaning including not only the compound itself but also a salt thereof, and an ion thereof. In addition, the expression of a compound has a meaning to include that a part of a structure is changed within a range in which an effect of the present invention is not impaired. Further, a compound for which substitution or non-substitution is not specified means that the compound may have a predetermined substituent within a range in which an effect of the present invention is not impaired. The same applies to the substituents and linking groups.

Also, in the present invention, the numerical range represented by “to” means a range including the numerical values described before and after “to” as the lower limit value and the upper limit value.

In the present invention, the term “composition” includes a mixture in which a component concentration varies within a range not impairing a desired function, in addition to a mixture in which a component concentration is constant (each component is uniformly dispersed).

In the present invention, an expression “having a main absorption wavelength range at a wavelength XX to YY nm” means that a wavelength at which the maximum absorption appears (that is, the maximal absorption wavelength) is present in the wavelength range of XX to YY nm.

Therefore, in a case where the maximal absorption wavelength is present in the above-mentioned wavelength range, the entire absorption range including this wavelength may be in the above-mentioned wavelength range or may also extend up to the outside of the above-mentioned wavelength range. In addition, in a case where there are a plurality of maximal absorption wavelengths, a maximal absorption wavelength at which highest light absorbance appears may be present in the above-mentioned wavelength range. That is, the maximal absorption wavelength other than the maximal absorption wavelength at which the highest light absorbance is exhibited may be present either inside or outside the wavelength range of XX to YY nm.

Therefore, the wavelength selective absorption filter according to an aspect of the present invention achieves both suppression of external light reflection and suppression (that is, a difference in tint between display light and reflected light of a display image is hardly visually recognized) of an influence of a reflected tint on an original tint of the display image, in which the suppression of a decrease in brightness of light emitted from an OLED is excellent in a case of being applied to a wide color gamut OLED display device.

The organic electroluminescent display device according to the aspect of the present invention includes the wavelength selective absorption filter according to the embodiment of the present invention, and realizes suppression of external light reflection, suppression of an influence of a reflected tint on the original tint of a display image, and suppression of a decrease in brightness.

### BRIEF DESCRIPTION OF THE DRAWINGS

FIG. 1 shows an absorption spectrum of a wavelength selective absorption filter No. 1 produced in Example.

FIG. 2 is a vertical cross-sectional view schematically showing a configuration of an OLED display device assumed for simulating external light reflection in Example.

### DESCRIPTION OF THE PREFERRED EMBODIMENTS

[Wavelength Selective Absorption Filter]

A wavelength selective absorption filter used in the present invention is a wavelength selective absorption filter that includes a resin, and dyes B, C, and D among the following four dyes A to D having a main absorption wavelength range in different wavelength regions, in which a light absorbance Ab (λ) of the wavelength selective absorption filter at a wavelength of λ nm satisfies a relationship of Relational Expressions (I) and (II).
Dye A: A dye having a main absorption wavelength range at a wavelength of 390 to 435 nm in the wavelength selective absorption filter
Dye B: A dye having a main absorption wavelength range at a wavelength of 480 to 520 nm in the wavelength selective absorption filter
Dye C: A dye having a main absorption wavelength range at a wavelength of 580 to 620 nm in the wavelength selective absorption filter
Dye D: A dye having a main absorption wavelength range at a wavelength of 680 to 780 nm in the wavelength selective absorption filter

Ab(500)/Ab(600)<0.7 Relational Expression (I)

Ab(430)/Ab(700)<3.0 Relational Expression (II)

In the present invention, the main absorption wavelength range of the dye in the wavelength selective absorption filter refers to a main absorption wavelength range of the dye measured in a state of the wavelength selective absorption filter. Specifically, in Examples described later, the measurement is performed under conditions described in the section of Maximal Absorption Value of Wavelength Selective Absorption Filter.

In the wavelength selective absorption filter according to the embodiment of the present invention, by containing at least the dyes B, C, and D among the four dyes A to D in combination, it is possible to produce a filter exhibiting a light absorption spectrum satisfying Relational Expressions (I) and (II). It is also preferable to combine the dye A in addition to the dyes B, C, and D.

In addition, light absorbance ratios described in Relational Expressions (I) and (II) and Relational Expressions (III) and (IV) are values calculated by using a value of a light absorbance Abₓ(λ) at each wavelength of λ nm of the wavelength selective absorption filter measured by a method described in Examples which will be described later.

An aspect of the wavelength selective absorption filter according to the embodiment of the present invention may be any aspect as long as the aspect can realize suppression of external light reflection, suppression (hereinafter, also simply referred to as “suppression of influence of reflected tint”) of influence of reflected tint on an original tint of a display image, and suppression (hereinafter, also simply referred to as “suppression of decrease in brightness”) of decrease in brightness of light emitted from an OLED in a case of being applied to a wide color gamut OLED display device. Examples of one aspect of the wavelength selective absorption filter according to the embodiment of the present invention include an aspect in which a dye including the dyes B to D is dispersed (preferably dissolved) in a resin. This dispersion may be any type of dispersion, such as a random type or a regular type.

The wavelength selective absorption filter according to the embodiment of the present invention has the configuration, and thus it is possible to suppress external light reflection and maintain the original tint of an image of the OLED display device at an excellent level. In addition, in a case of being applied to the wide color gamut OLED display device, it is possible to satisfy the suppression of the decrease in brightness of the light emitted from the OLED. The reason for this is not clear, but can be considered as follows.

In the wavelength selective absorption filter according to the embodiment of the present invention, each of the dyes A to D has main absorption wavelength ranges in wavelength regions 390 to 435 nm, 480 to 520 nm, 580 to 620 nm, and 680 to 780 nm, which do not overlap with B (Blue, 460 nm), G (Green, 520 nm), and R (Red, 620 nm) which are used as light emitting sources of the OLED display device. Among these, the (corresponding) dyes B and C having a main absorption wavelength range of 480 to 520 nm and 580 to 620 nm, which have particularly high visual sensitivity, the (corresponding) dye D having a main absorption wavelength range of 680 to 780 nm, at which a substrate reflectivity is likely to be high, are contained, and Relational Expressions (I) and (II) are satisfied, so that in the wavelength selective absorption filter according to the embodiment of the present invention, it is possible to suppress reflection of external light and bring the reflected tint close to a tint (the original tint of the display image) of a display light, and in a case of being applied to the wide color gamut OLED display device comprising a light source having a narrow half-width of emitted light of G (green), it is possible to suppress the decrease in brightness of the light emitted from the OLED.

It is preferable that a preferred range of the reflected tint of the wavelength selective absorption filter according to the embodiment of the present invention is close to an original white display tint of the display device.

A white display tint of the display device shows a color temperature of 6500 K or higher as sunlight, and a color temperature is generally 6500 to 12000 K and preferably 8000 to 12000 K. The color temperature is represented by coordinates of an xy chromaticity diagram as the following expression.

Color temperature of 6500 to 12000 K: (0.269,0.280)≤(x,y)≤(0.313,0.329)

Color temperature of 8000 to 12000 K: (0.269,0.280)≤(x,y)≤(0.295,0.305)

That is, the reflected tint of the wavelength selective absorption filter according to the embodiment of the present invention is preferably in a range of 6500 to 12000 K of the color temperature and more preferably in a range of 8000 to 12000 K of the color temperature.

In ranges of Ab (500)/Ab (600) defined by Relational Expression (I) and ranges of Ab (430)/Ab (700) defined by Relational Expression (II), each of preferred ranges is as follows.

An upper limit value of Ab (500)/Ab (600) in Relational Expression (I) is less than 0.70, and is preferably 0.60 or less, more preferably 0.50 or less, still more preferably 0.40 or less, and particularly preferably 0.35 or less. A lower limit value is not particularly limited, but is practically 0.05 or more, preferably 0.10 or more, more preferably 0.15 or more, and still more preferably 0.20 or more. That is, 0.05≤Ab (500)/Ab (600)<0.70 is practical, 0.10≤Ab (500)/Ab (600)≤0.60 is preferable, 0.15≤Ab (500)/Ab (600)≤0.50 is more preferable, 0.20≤Ab (500)/Ab (600)≤0.40 is still more preferable, and 0.20≤Ab (500)/Ab (600)≤0.35 is particularly preferable.

An upper limit value of Ab (430)/Ab (700) in Relational Expression (II) is less than 3.0, and from the viewpoint of further suppressing the decrease in brightness in a case of being applied to the wide color gamut OLED display device, is preferably less than 2.0, more preferably less than 1.5, and still more preferably less than 1.0, and from the viewpoint of further suppressing the influence of the reflected tint on the original tint of the display image, is particularly preferably 0.80 or less, and more particularly preferably 0.70 or less. The lower limit value is not particularly limited, but may be 0 or more, preferably 0.10 or more, more preferably 0.15 or more, still more preferably 0.20 or more, and particularly preferably 0.30 or more. That is, it suffices that 0≤Ab (430)/Ab (700)<3.0, and it is preferably 0.10≤Ab (430)/Ab (700)<2.0, more preferably 0.15≤Ab (430)/Ab (700)<1.5, still more preferably 0.20≤Ab (430)/Ab (700)<1.0, particularly preferably 0.30≤Ab (430)/Ab (700)≤0.80, and more particularly preferably 0.30≤Ab (430)/Ab (700)≤0.70.

In a case where Relational Expressions (I) and (II) satisfy the preferred ranges, it is easier to further realize a reduction (suppression of external light reflection) in reflectivity caused by the wavelength selective absorption filter, suppression of the influence of the reflected tint on the original tint of the display image, and suppression of the decrease in brightness in a case of being applied to the wide color gamut OLED display device.

The wavelength selective absorption filter according to the embodiment of the present invention preferably satisfies at least one of Relational Expressions (III) or (IV), and more preferably satisfies both Relational Expressions (III) and (IV).

Ab(430)/Ab(600)<1.0 Relational Expression (III)

Ab(700)/Ab(600)<2.0 Relational Expression (IV)

An upper limit value of Ab (430)/Ab (600) in Relational Expression (III) is less than 1.0, and is preferably 0.80 or less, more preferably 0.60 or less, still more preferably 0.40 or less, and particularly preferably 0.30 or less. A lower limit value is not particularly limited, but may be 0 or more, and is preferably 0.03 or more, more preferably 0.05 or more, still more preferably 0.10 or more, and particularly preferably 0.15 or more. That is, it suffices that 0≤Ab (430)/Ab (600)<1.0, and 0.03≤Ab (430)/Ab (600)≤0.80 is preferable, 0.05≤Ab (430)/Ab (600)≤0.60 is more preferable, 0.10≤Ab (430)/Ab (600)≤0.40 is still more preferable, and 0.15≤Ab (430)/Ab (600)≤0.30 is particularly preferable.

An upper limit value of Ab (700)/Ab (600) in Relational Expression (IV) is less than 2.0, preferably less than 1.6, more preferably less than 1.4, still more preferably 1.2 or less, and particularly preferably 1.1 or less. From the viewpoint of further suppressing the influence of the reflected tint on the original tint of the display image, in particular, the upper limit value is preferably 1.0 or less, more preferably 0.90 or less, and still more preferably 0.80 or less. A lower limit value is not particularly limited, but may be 0 or more, preferably 0.03 or more, more preferably 0.05 or more, still more preferably 0.10 or more, particularly preferably 0.15 or more, and more particularly preferably 0.20 or more. That is, it suffices that 0≤Ab (700)/Ab (600)<2.0, and it is preferably 0.03≤Ab (700)/Ab (600)<1.6, more preferably 0.05≤Ab (700)/Ab (600)<1.4, still more preferably 0.10≤Ab (700)/Ab (600)≤1.2, and particularly preferably 0.15≤Ab (700)/Ab (600)≤1.1. Among these, 0.20≤Ab (700)/Ab (600)≤1.0 is preferable, 0.20≤Ab (700)/Ab (600)≤0.90 is more preferable, and 0.20≤Ab (700)/Ab (600)≤0.80 is still more preferable.

In a case where at least one (preferably both) of Relational Expressions (III) or (IV) is satisfied in addition to Relational Expressions (I) and (II), it is easier to further realize the reduction (suppression of external light reflection) in the reflectivity caused by the wavelength selective absorption filter, the suppression of the influence of the reflected tint on the original tint of the display image, and the suppression of the decrease in brightness in a case of being applied to the wide color gamut OLED display device.

In a case where the wavelength selective absorption filter according to the embodiment of the present invention does not contain the dye A or the like, and thus a value of Ab (430) is 0, both a value of Ab (430)/Ab (700) in Relational Expression (II) and a value of Ab (430)/Ab (600) in Relational Expression (III) are 0.

On the other hand, in a case where the wavelength selective absorption filter according to the embodiment of the present invention contains the dye A or a base of the absorption of the dye B is present at a wavelength of 430 nm or similar steps are performed, and thus exhibits a light absorbance more than 0 at Ab (430), each of the lower limit value of Ab (430)/Ab (700) in Relational Expression (II) and the lower limit value of Ab (430)/Ab (600) in Relational Expression (III) may be 0 or more, and is preferably the preferred value or more.

However, in a case where the wavelength selective absorption filter according to the embodiment of the present invention contains the dye A, it is more preferable that the upper limit value of Ab (430)/Ab (700) in Relational Expression (II) is less than 1.0 and Relational Expression (III) is satisfied. In this case, from a relationship between Relational Expression (I) (Ab (500)/Ab (600)<0.7) and Relational Expression (III) (Ab (430)/Ab (600)<1.0), Ab (430)/Ab (500)<0.7 is satisfied, and Ab (430) has a smaller value than any of Ab (500), Ab (600), or Ab (700).

### <Dye>

The wavelength selective absorption filter according to the embodiment of the present invention contains the dye B, dye C, and dye D. In the present invention, the “dye” is particularly not limited, as long as the dye can satisfy the suppression of external light reflection and the suppression of the decrease in brightness in a case of being applied to the wide color gamut OLED display device, by dispersing (preferably dissolving) in the resin and can maintain the original tint of the image of the OLED display device at an excellent level in the wavelength selective absorption filter.

The wavelength selective absorption filter according to the embodiment of the present invention may contain one or more kinds of the dyes B, C, and D, each independently, or may contain two or more kinds thereof.

The wavelength selective absorption filter according to the embodiment of the present invention preferably contains the dye A in addition to the dyes B, C, and D, and can also contain a dye other than the dyes A to D (other dyes) within a range where effects of the present invention are exhibited.

### (Dye A)

The dye A is not particularly limited as long as the dye has the main absorption wavelength range in a wavelength of 390 to 435 nm in the wavelength selective absorption filter, and various dyes can be used.

A wavelength range of the dye A having a main absorption wavelength range is preferably 395 to 435 nm, more preferably 400 to 435 nm, and still more preferably 405 to 435 nm.

As the dye A, a coloring agent represented by General Formula (A1) is preferable in that an absorption waveform in the main absorption wavelength range is sharp.

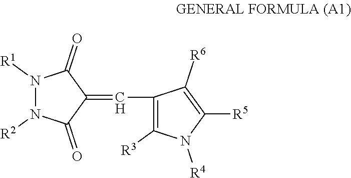

In Formula (A1), R¹ and R² each independently represent an alkyl group or an aryl group, R³ to R⁶ each independently represent a hydrogen atom or a substituent, and R⁵ and R⁶ may be bonded to each other to form a 6-membered ring.

With regard to definition and a preferred range of each substituent in General Formula (A1), each of descriptions related to each substituent of coloring agents represented by General Formula (A1) described in WO2022/138925A can be applied unless otherwise specified.

Further, from the viewpoint of heat resistance and light resistance, it is also preferable that both R¹ and R² in Formula (A1) are aryl groups.

In a case where R¹ and R² each independently represent an aryl group, R³, R⁵, and R⁶ are each independently a hydrogen atom, an alkyl group, or an aryl group, and at least one of R³ or R⁶ is preferably a hydrogen atom. Among these, from the viewpoint of heat resistance and light resistance, a case where R³ represents a hydrogen atom, and R⁵ and R⁶ each independently represent an alkyl group or an aryl group is more preferable. A case where R³ represents a hydrogen atom and R⁵ and R⁶ each independently represent an alkyl group is still more preferable. A case where R³ represents a hydrogen atom, R⁵ and R⁶ each independently represent an alkyl group, and R⁵ and R⁶ are bonded to each other to form a ring and fused with a pyrrole ring to form an indole ring together with the pyrrole ring is particularly preferable. That is, the coloring agent represented by General Formula (A1) is particularly preferably a coloring agent represented by General Formula (A2).

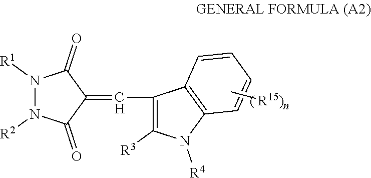

In Formula (A2), R¹ to R⁴ each have the same meanings as R¹ to R⁴ in General Formula (A1), and preferable embodiments are also the same.

In Formula (A2), R¹⁵ represents a substituent. Examples of the substituent that can be employed as R¹⁵ can include substituents included in a substituent group A described in the description of the coloring agent represented by General Formula (A1) described in the WO2022/138925A. As R¹⁵, an alkyl group, an aryl group, a halogen atom, an acyl group, an amino group, or an alkoxycarbonyl group is preferable.

For the alkyl group and the aryl group, which can be employed as R¹⁵, the descriptions regarding the alkyl group and the aryl group, which can be employed as R³, R⁵, and R⁶, can be applied respectively.

Examples of the halogen atom that can be employed as R¹⁵ include a chlorine atom, a bromine atom, and an iodine atom.

Examples of the acyl group that can be employed as R¹⁵ include an acetyl group, a propionyl group, and a butyroyl group.

For the amino group that can be employed as R¹⁵, the description regarding the amino group that can be contained in the substituted aryl group as R⁴ can be applied. Further, a nitrogen-containing heterocyclic group having a 5-membered to 7-membered ring in which an alkyl group on the nitrogen atom of the amino group is bonded to form a ring is also preferable. As the alkoxycarbonyl group that can be employed as R¹⁵, an alkoxycarbonyl group having 2 to 5 carbon atoms is preferable, and examples thereof include methoxycarbonyl, ethoxycarbonyl, normal propoxycarbonyl, and isopropoxycarbonyl.

n represents an integer of 0 to 4. n is not particularly limited, and is, for example, preferably 0 or 1.

Specific examples of the coloring agent represented by General Formula (A1) include compounds described in paragraphs [0063] to [0065] of WO2022/138925A. However, the present invention is not limited thereto.

In addition, in addition to the specific examples, specific examples of the coloring agent represented by any one of General Formulae (3) to (5) include the compounds described in paragraphs [0071] to [0080] of WO2021/132674A. However, the present invention is not limited thereto.

As the dye A, in addition to the coloring agent represented by General Formula (A1), the compounds described in paragraphs 0012 to 0067 of JP2007-53241A (JP-H05-53241A) and the compounds described in paragraphs 0011 to 0076 of JP2707371B can also be preferably used.

### (Dye B and Dye C)

The dye B is not particularly limited as long as the dye has the main absorption wavelength range in a wavelength of 480 to 520 nm in the wavelength selective absorption filter, and various dyes can be used.

In addition, the dye C is not particularly limited as long as the dye has the main absorption wavelength range in a wavelength of 580 to 620 nm in the wavelength selective absorption filter, and various dyes can be used.

A wavelength range of the dye B having a main absorption wavelength range is preferably 485 to 520 nm, more preferably 490 to 520 nm, and still more preferably 490 to 515 nm.

A wavelength range of the dye C having a main absorption wavelength range is preferably 580 to 615 nm, more preferably 580 to 610 nm, and still more preferably 580 to 610 nm.

Specific examples of the dye B include, for example, individual coloring agents (dyes) such as pyrrole methine (PM)-based dyes, rhodamine (RH)-based dyes, boron dipyrromethene (BODIPY)-based dyes, and squaraine (SQ)-based dyes.

Specific examples of the dye C include, for example, individual coloring agents (dyes) such as tetraaza porphyrin (TAP)-based dyes, squaraine-based dyes, and cyanine (CY)-based dyes.

Among these, as the dye B and the dye C, squaraine-based coloring agents are preferable, and squaraine-based coloring agents represented by General Formula (1) are more preferable in that an absorption waveform in the main absorption wavelength range is sharp. By using the coloring agent having a sharp absorption waveform as described above as the dye B and the dye C, Relational Expressions (I) and (II) can be satisfied at a preferable level, and the original tint of the image of the OLED display device can be maintained at a more excellent level.

That is, in the wavelength selective absorption filter according to the embodiment of the present invention, from the viewpoint of suppressing the change in tint, it is preferable that at least one of the dye B or the dye C is a squaraine-based coloring agent (preferably, a squaraine-based coloring agent represented by General Formula (1)), and it is more preferable that both the dye B and the dye C are squaraine-based coloring agents (preferably, squaraine-based coloring agents represented by General Formula (1)).

In the present invention, in the coloring agents represented by each of General Formulae, a cation is present in a delocalized manner, and a plurality of tautomer structures are present. Therefore, in the present invention, in a case where at least one tautomer structure of a certain coloring agent matches with each of the General Formulae, a certain coloring agent is considered as the coloring agent represented by each of General Formulae. Therefore, a coloring agent represented by a specific General Formula can also be said to be a coloring agent having at least one tautomer structure that can be represented by the specific General Formula. In the present invention, a coloring agent represented by a general formula may have any tautomer structure as long as at least one tautomer structure of the coloring agent matches the general formula.

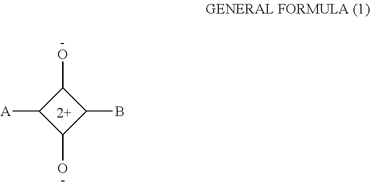

In General Formula (1), A and B each independently represent an aryl group which may have a substituent, a heterocyclic group which may have a substituent, or —CH=G. G represents a heterocyclic group which may have a substituent.

With regard to definition and a preferred range of each substituent in General Formula (1), each of descriptions related to each substituent of coloring agents represented by General Formula (1) described in WO2021/132674A can be applied unless otherwise specified.

A preferable embodiment of the coloring agent represented by General Formula (1) includes a coloring agent represented by General Formula (2).

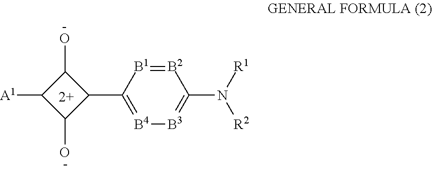

In General Formula (2), A¹ is the same as A in General Formula (1). Among these, a heterocyclic group which is a nitrogen-containing 5-membered ring is preferable.

In General Formula (2), R¹ and R² each independently represent a hydrogen atom or a substituent. R¹ and R² may be the same as or different from each other, and may be bonded together to form a ring.

The substituent that can be employed as R¹ and R² is not particularly limited, but examples thereof include an alkyl group (a methyl group, an ethyl group, a propyl group, an isopropyl group, a butyl group, a t-butyl group, an isobutyl group, a pentyl group, a hexyl group, an octyl group, a dodecyl group, a trifluoromethyl group, or the like), a cycloalkyl group (a cyclopentyl group, a cyclohexyl group, or the like), an alkenyl group (a vinyl group, an allyl group, or the like), an alkynyl group (an ethynyl group, a propargyl group, or the like), an aryl group (a phenyl group, a naphthyl group, or the like), a heteroaryl group (a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, a phthalazyl group, or the like), a heterocyclic group (also referred to as a heterocycle group, such as a pyrrolidyl group, an imidazolidyl group, a morpholyl group, or an oxazolidyl group), an alkoxy group (a methoxy group, an ethoxy group, a propyloxy group, or the like), a cycloalkoxy group (a cyclopentyloxy group, a cyclohexyloxy group, or the like), an aryloxy group (a phenoxy group, a naphthyloxy group, or the like), a heteroaryloxy group (an aromatic heterocyclic oxy group), an alkylthio group (a methylthio group, an ethylthio group, a propylthio group, or the like), a cycloalkylthio group (a cyclopentylthio group, a cyclohexylthio group, or the like), an arylthio group (a phenylthio group, a naphthylthio group, or the like), a heteroarylthio group (an aromatic heterocyclic thio group), an alkoxycarbonyl group (a methyloxycarbonyl group, an ethyloxycarbonyl group, a butylxycarbonyl group, an octyloxycarbonyl group, or the like), an aryloxycarbonyl group (a phenyloxycarbonyl group, a naphthyloxycarbonyl group, or the like), a phosphoryl group (dimethoxyphosphonyl, diphenylphosphoryl), a sulfamoyl group (an aminosulfonyl group, a methylaminosulfonyl group, a dimethylaminosulfonyl group, a butylaminosulfonyl group, a cyclohexylaminosulfonyl group, an octylaminosulfonyl group, a phenylaminosulfonyl group, a 2-pyridylaminosulfonyl group, or the like), an acyl group (an acetyl group, an ethylcarbonyl group, a propylcarbonyl group, a cyclohexylcarbonyl group, an octylcarbonyl group, 2-ethylhexylcarbonyl group, phenylcarbonyl group, naphthylcarbonyl group, pyridylcarbonyl group, or the like), an acyloxy group (an acetyloxy group, an ethylcarbonyloxy group, a butylcarbonyloxy group, an octylcarbonyloxy group, a phenylcarbonyloxy group, or the like), an amide group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, or the like), a sulfonylamide group (a methylsulfonylamino group, an octylsulfonylamino group, a 2-ethylhexylsulfonylamino group, a trifluoromethylsulfonylamino group, or the like), a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, or the like), a ureido group (a methylureido group, an ethylureido group, a pentylureido group, a cyclohexylureido group, an octylureido group, a dodecylureido group, a phenylureido group, a naphthylureido group, a 2-pyridylamino group, or the like), an alkylsulfonyl group (a methylsulfonyl group, an ethylsulfonyl group, a butylsulfonyl group, a cyclohexylsulfonyl group, a 2-ethylhexylsulfonyl group, or the like), an arylsulfonyl group (a phenylsulfonyl group, a naphthylsulfonyl group, a 2-pyridylsulfonyl group, or the like), an amino group (an amino group, an ethylamino group, a dimethylamino group, a butylamino group, a dibutylamino group, a cyclopentylamino group, a 2-ethylhexylamino group, a dodecylamino group, an anilino group, a naphthylamino group, a 2-pyridylamino group, or the like), an alkylsulfonyloxy group (methanesulfonyloxy), a cyano group, a nitro group, a halogen atom (a fluorine atom, a chlorine atom, a bromine atom, or the like), and a hydroxyl group.

Among these, an alkyl group, an alkenyl group, an aryl group, or a heteroaryl group is preferable, an alkyl group, an aryl group, or a heteroaryl group is more preferable, and an alkyl group is further preferable.

The substituent that can be employed as R¹ and R² may further have a substituent. As the substituent that the substituent that can be employed as R¹ and R² may further have, the above-mentioned substituents that can be employed as R¹ and R² are exemplified. In addition, R¹ and R² may be bonded to each other or bond with a substituent that B² or B³ has to form a ring. As the ring that is formed in this case, a heterocycle or a heteroaryl ring is preferable, and the size of the ring being formed is not particularly limited, and a 5-membered ring or a 6-membered ring is preferable.

In General Formula (2), B¹, B², B³, and B⁴ each independently represent a carbon atom or a nitrogen atom. The ring including B¹, B², B³, and B⁴ is an aromatic ring. At least two or more of 1 to B⁴ are preferably carbon atoms, and more preferably all of 1 to B⁴ are carbon atoms.

The carbon atom that can be employed as B¹ to B⁴ has a hydrogen atom or a substituent. Among carbon atoms that can be employed as B¹ to B⁴, the number of carbon atoms having a substituent is not particularly limited, but is preferably zero, one, or two and more preferably one. Particularly, it is preferable that 1 and B⁴ are carbon atoms and at least one has a substituent.

The substituent that the carbon atom that can be employed as 1 to B⁴ has is not particularly limited, and examples thereof include the above-mentioned substituents that can be employed as R¹ and R². Among these, an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxyl group is preferable, and an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxyl group is more preferable.

As the substituent that the carbon atom that can be employed as B¹ and B⁴ has, an alkyl group, an alkoxy group, a hydroxyl group, an amide group, a sulfonylamide group, or a carbamoyl group is still more preferable, an alkyl group, an alkoxy group, a hydroxyl group, an amide group, or a sulfonylamide group is particularly preferable, and a hydroxyl group, an amide group, or a sulfonylamide group is most preferable.

It is still more preferable that the substituent that can be possessed by the carbon atom that can be employed as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron-withdrawing group (for example, an alkoxycarbonyl group, an acyl group, a cyano group, a nitro group, or a halogen atom).

The coloring agent represented by General Formula (2) is preferably a coloring agent represented by any of General Formulae (3), (4), and (5).

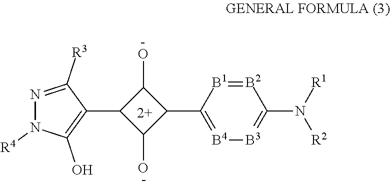

In General Formula (3), R¹ and R² each independently represent a hydrogen atom or a substituent, and have the same meanings as R¹ and R² in General Formula (2), and the preferable ranges are also the same.

In General Formula (3), B¹ to B⁴ each independently represent a carbon atom or a nitrogen atom, have the same meanings as B¹ to B⁴ in General Formula (2), and the preferable ranges are also the same.

In General Formula (3), R³ and R⁴ each independently represent a hydrogen atom or a substituent. The substituent that can be employed as R³ and R⁴ is not particularly limited, and the same substituents as the substituents that can be employed as R¹ and R² can be exemplified.

However, as the substituents that can be employed as R³, an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom is preferable, an alkyl group, an aryl group, or an amino group is more preferable, and an alkyl group is still more preferable.

As the substituent that can be employed as R⁴, an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group is preferable, an alkyl group, an alkoxycarbonyl group, an acyl group, a carbamoyl group, or an aryl group is more preferable, and an alkyl group is still more preferable.

The alkyl group that can be employed as R³ and R⁴ may be either linear, branched, or cyclic, and it is preferably linear or branched. The alkyl group preferably has 1 to 12 carbon atoms and more preferably 1 to 8 carbon atoms. An example of the alkyl group is preferably a methyl group, an ethyl group, an n-propyl group, an isopropyl group, a t-butyl group, a 2-ethylhexyl group, or a cyclohexyl group, and more preferably a methyl group or a t-butyl group.

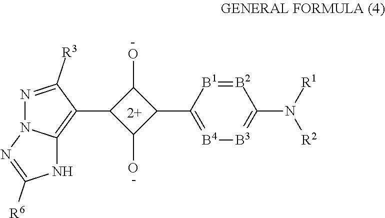

In General Formula (4), R¹ and R² each independently represent a hydrogen atom or a substituent, and have the same meanings as R¹ and R² in General Formula (2), and the preferable ranges are also the same.

In General Formula (4), B¹ to B⁴ each independently represent a carbon atom or a nitrogen atom, have the same meanings as B¹ to B⁴ in General Formula (2), and the preferable ranges are also the same.

In General Formula (4), R⁵ and R⁶ each independently represent a hydrogen atom or a substituent. The substituent that can be employed as R⁵ and R⁶ is not particularly limited, and the same substituents as the substituents that can be employed as R¹ and R² can be exemplified. However, the substituent that can be employed as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, an ureido group, or a carbamoyl group, more preferably an alkyl group, an alkoxy group, an acyl group, an amide group, or an amino group, and still more preferably an alkyl group.

The alkyl group that can be employed as R⁵ has the same meaning as the alkyl group that can be employed as R³ in General Formula (3), and the preferable range is also the same. In General Formula (4), the substituent that can be employed as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be employed as R⁶ has the same meaning as the alkyl group that can be employed as R⁴ in General Formula (3), and the preferable range is also the same.

The aryl group that can be employed as R⁶ is preferably an aryl group having 6 to 12 carbon atoms, and more preferably a phenyl group. This aryl group may have a substituent, and examples of such a substituent include a group included in the following substituent group A, and an alkyl group, a sulfonyl group, an amino group, an acylamino group, a sulfonylamino group, or the like, which have 1 to 10 carbon atoms, is particularly preferable. This substituent may further have a substituent. Specifically, the substituent is preferably an alkylsulfonylamino group.

### —Substituent Group A—

A halogen atom, an alkyl group, an alkenyl group, an alkynyl group, an aryl group, a heterocyclic group, a cyano group, a hydroxyl group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, a sulfonyl group (including an alkyl or arylsulfinyl group), an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group, and the like.

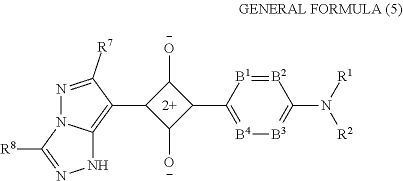

In General Formula (5), R¹ and R² each independently represent a hydrogen atom or a substituent, and have the same meanings as R¹ and R² in General Formula (2), and the preferable ranges are also the same.

In General Formula (5), B¹ to B⁴ each independently represent a carbon atom or a nitrogen atom, have the same meanings as B¹ to B⁴ in General Formula (2), and the preferable ranges are also the same.

In General Formula (5), R⁷ and R⁸ each independently represent a hydrogen atom or a substituent. The substituent that can be employed as R⁷ and R⁸ is not particularly limited, and examples thereof can include the same ones as the substituents that can be employed as R¹ and R².

However, the preferred range, the more preferred range, and the still more preferred range of the substituent that can be employed as R⁷ are the same as those of the substituent that can be employed as R⁵ in General Formula (4). The alkyl group that can be employed as R⁵ has the same meaning as the alkyl group that can be employed as R³, and the preferable range is also the same.

In General Formula (5), a preferable range, a more preferable range, and a still more preferable range of the substituent that can be employed as R⁸ are the same as the substituent that can be employed as R⁶ in General Formula (4). The preferable ranges of the alkyl group and the aryl group that can be employed as R⁸ have the same meaning as the alkyl group and the aryl group that can be employed as R⁶ in General Formula (4), and the preferable ranges are also the same.

As the squaraine-based coloring agent, a squaraine coloring agent represented by any one of General Formulae (1) to (5) can be used without particular limitation. Examples thereof include compounds described in, for example, JP2006-160618A, WO2004/005981A, WO2004/007447A, Dyes and Pigment, 2001, 49, pp. 161 to 179, WO2008/090757A, WO2005/121098A, and JP2008-275726A.

Specific examples of the coloring agent represented by any of General Formula (1) to General Formula (5) include the compounds described in paragraphs [0067] to [0070] of WO2021/132674A. However, the present invention is not limited thereto.

In addition, in addition to the specific examples, specific examples of the coloring agent represented by any one of General Formulae (3) to (5) include the compounds described in paragraphs [0071] to [0080] of WO2021/132674A. However, the present invention is not limited thereto.

As a preferable embodiment of the coloring agent represented by General Formula (1), a coloring agent represented by General Formula (6) is exemplified.

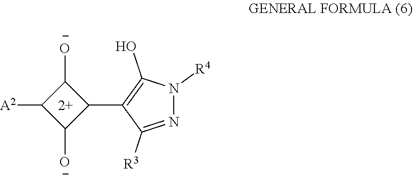

In General Formula (6), R³ and R⁴ each independently represent a hydrogen atom or a substituent and have the same meanings as R³ and R⁴ in General Formula (3), and the preferable ranges are also the same.

In General Formula (6), A² has the same meaning as A in General Formula (1).

Among these, a heterocyclic group which is a nitrogen-containing 5-membered ring is preferable.

The coloring agent represented by General Formula (6) is preferably a coloring agent represented by any one of General Formulae (7), (8), or (9).

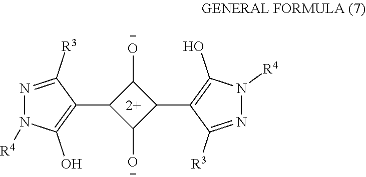

In General Formula (7), R³ and R⁴ each independently represent a hydrogen atom or a substituent, and have the same meanings as R³ and R⁴ in General Formula (3), and the preferable ranges are also the same. Two R³'s and two R⁴'s may be the same as or different from each other.

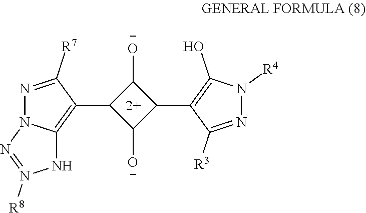

In General Formula (8), R³ and R⁴ each independently represent a hydrogen atom or a substituent, and have the same meanings as R³ in General Formula (3), and the preferable ranges are also the same.

In General Formula (8), R⁵ and R⁶ each independently represent a hydrogen atom or a substituent, and have the same meanings as R⁵ and R⁶ in General Formula (4), and the preferable ranges are also the same.

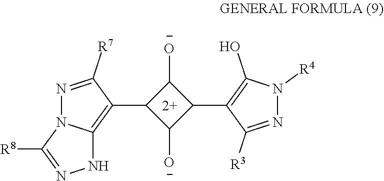

In General Formula (9), R³ and R⁴ each independently represent a hydrogen atom or a substituent, and have the same meanings as R³ in General Formula (3), and the preferable ranges are also the same.

In General Formula (9), R⁷ and R⁸ each independently represent a hydrogen atom or a substituent, and have the same meanings as R⁷ and R⁸ in General Formula (5), and the preferable ranges are also the same.

In the present invention, in a case where a squaraine-based coloring agent is used as the dye B, any squaraine-based coloring agent can be used without particular limitations as long as the squaraine-based coloring agent is a squaraine-based coloring agent represented by any one of General Formulae (6) to (9). Examples thereof can include the compounds described in, for example, JP2002-97383A and JP2015-68945A.

Specific examples of the squaraine-based coloring agent represented by any one of General Formulae (6) to (9) include the compounds described in paragraphs [0091] to [0095] of WO2021/132674A. However, the present invention is not limited thereto.

### (Quencher-Embedded Coloring Agent)

The squaraine-based coloring agent represented by General Formula (1) may be a quencher-embedded coloring agent in which a quencher portion is linked to a coloring agent by a covalent bond via a linking group. The quencher-embedded coloring agent can also be preferably used as the coloring agent of at least one of the dye B or the dye C. That is, the quencher-embedded coloring agent is counted as the dye B or dye C according to the wavelength having the main absorption wavelength range.

Examples of the quencher portion include the ferrocenyl group in the above-mentioned substituent X. In addition, the quencher portion in a quencher compound described in paragraphs [0199] to [0212] and paragraphs [0234] to [0310] of WO2019/066043A can be exemplified.

Among the squaraine-based coloring agents represented by General Formula (1), specific examples of the coloring agent corresponding to the quencher-embedded coloring agent include the compounds described in paragraphs [0097] to [0114] of WO2021/132674A. However, the present invention is not limited thereto.

### (Dye D)

The dye D is not particularly limited as long as the dye has the main absorption wavelength range in a wavelength of 680 to 780 nm in the wavelength selective absorption filter, and various dyes can be used.

Specific examples of the dye D include, for example, porphyrin-based, squaraine-based, and cyanine (CY)-based coloring agents (dyes).

A wavelength range of the dye D having a main absorption wavelength range is preferably 680 to 760 nm, more preferably 680 to 740 nm, and still more preferably 680 to 720 nm.

It is preferable that, from the viewpoint that the absorption waveform is sharp, the dye D is at least one of a coloring agent represented by General Formula (D1) or the coloring agent represented by General Formula (1).

### (Coloring Agent Represented by General Formula (D1))

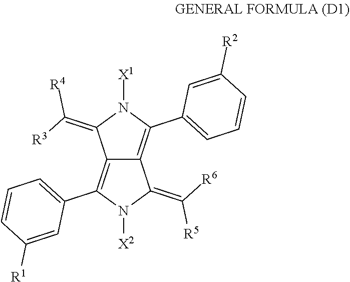

In Formula (D1), R¹ and R² each independently represent a substituent, R³ to R⁶ each independently represent a hydrogen atom or a substituent, R³ and R⁴, and R⁵ and R⁶ may be bonded to each other to form a ring, and X¹ and X² each independently represent a hydrogen atom or a substituent.

With regard to definition and a preferred range of each substituent in General Formula (D1), each of descriptions related to each substituent of coloring agents represented by General Formula (D1) described in WO2021/14973A can be applied unless otherwise specified.

The coloring agent represented by General Formula (D1) is preferably a coloring agent represented by General Formula (D2).

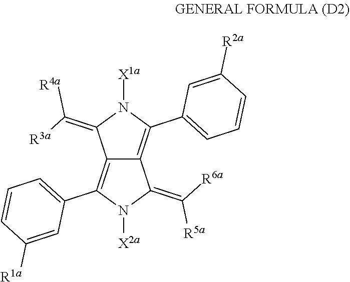

In Formula (D2), R^{1a} and R^{2a} each independently represent a substituent, and R^{3a} to R^{6a} each independently represent a hydrogen atom or a substituent, and R^{3a} and R^{4a}, and R^{5a} and R^{6a} may be bonded to each other to form a ring, respectively, and X^{1a} and X^{2a} each independently represent a hydrogen atom or —BR^{21a}R^{22a}, R^{21a} and R^{22a} each independently represent a substituent, and R^{21a} and R^{22a} may be bonded to each other to form a ring.

In Formula (D2), each of R^{1a} to R^{6a}, X^{1a}, X^{2a}, R^{21a}, and R^{22a} has the same meanings as R¹ to R⁶, X¹, X², R²¹, and R²² in the Formula (D1), and the preferable range is also the same.

The coloring agent represented by General Formula (D1) is more preferably a coloring agent represented by General Formula (D3).

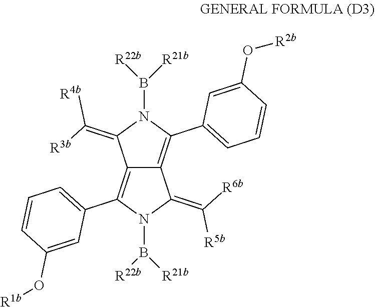

In Formula (D3), R^{1b} and R^{2b} each independently represent a branched alkyl group, R^{3b} to R^{6b} each independently represent a hydrogen atom or a substituent, R^{3b} and R^{4b}, R^{5b} and R^{6b} may be bonded to each other to form a ring, R^{21b} and R^{22b} each independently represent a substituent, and R^{21b} and R^{22b} may be bonded to each other to form a ring.

R^{1b} and R^{2b} each independently represent a branched alkyl group. The number of carbon atoms is preferably 3 to 40. A lower limit thereof is, for example, more preferably 5 or more, still more preferably 8 or more, and still further preferably 10 or more. An upper limit thereof is more preferably 35 or less, and still more preferably 30 or less. The number of branches in the branched alkyl group is preferably 2 to 10 and more preferably 2 to 8.

R^{3b} to R^{6b}, and R^{21b} and R^{22b} have the same meanings as R³ to R⁶, R²¹, and R²² in the Formula (D1), respectively, and the preferable range is also the same.

That is, R^{3b} to R^{6b} preferably have a combination in which any one of R^{3b} or R^{4b} is an electron-withdrawing group and the other is a heteroaryl group, and any one of R^{5b} or R^{6b} is an electron-withdrawing group and the other is a heteroaryl group. The electron-withdrawing group is preferably a cyano group.

R^{21b} and R^{22b} are each independently preferably a halogen atom, an alkyl group, an alkoxy group, an aryl group, or a heteroaryl group, more preferably a halogen atom, or an aryl group, and still more preferably an aryl group.

Specific examples of the coloring agent represented by General Formula (D1) include compounds described in paragraphs [0189] to [0197] of WO2021/14973A. However, the present invention is not limited thereto.

### (Coloring Agent Represented by General Formula (1))

In a case where the dye D is a coloring agent represented by General Formula (1), a coloring agent represented by General Formula (14) is also preferable.

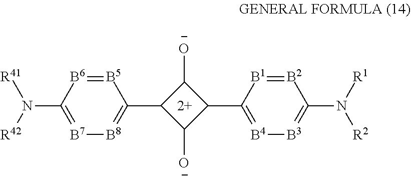

In General Formula (14), R¹ and R² each independently represent a hydrogen atom or a substituent. R¹ and R² may be the same as or different from each other, and may be bonded together to form a ring.

The substituent that can be employed as R¹ and R² is not particularly limited. However, examples thereof include, in the substituent X, an alkyl group (including a cycloalkyl group), an alkenyl group, an alkynyl group, an aryl group, a heterocyclic group (including an aromatic heterocyclic group and an aliphatic heterocyclic group), an alkoxy group, a cycloalkoxy group, an aryloxy group, a heteroaryloxy group, an alkylthio group, a cycloalkylthio group, an arylthio group, a heteroarylthio group, an alkoxycarbonyl group, an aryloxycarbonyl group, a phosphoryl group, a sulfamoyl group, an acyl group, an acyloxy group, an amide group, a sulfonylamide group, a carbamoyl group, a ureido group, an alkylsulfonyl group, an arylsulfonyl group, an amino group, an alkylsulfonyloxy group, a cyano group, a nitro group, a halogen atom, and a hydroxyl group.

In addition, R⁴¹ and R⁴² also have the same meaning as R¹ and R² described above.

R¹, R², R⁴¹, and R⁴² may further have a substituent. Examples of the substituent which may be further contained include the substituent X.

Among the above, R¹, R², R⁴¹, and R⁴² are preferably an alkyl group, an alkenyl group, an aryl group, or a heteroaryl group, more preferably an alkyl group, an aryl group, or a heteroaryl group, and still more preferably an alkyl group or an aryl group is.

In General Formula (14), B¹, B², B³, and B⁴ each independently represent a carbon atom or a nitrogen atom. The ring including B¹, B², B³, and B⁴ is an aromatic ring. At least two or more of B¹ to B⁴ are preferably carbon atoms, and more preferably all of B¹ to B⁴ are carbon atoms.

The carbon atom that can be employed as B¹ to B⁴ has a hydrogen atom or a substituent. Among carbon atoms that can be employed as B¹ to B⁴, the number of carbon atoms having a substituent is not particularly limited, but is preferably zero, one, or two and more preferably one. Particularly, it is preferable that B¹ and B⁴ are carbon atoms and at least one has a substituent.

The substituent that the carbon atom that can be employed as B¹ to B⁴ has is not particularly limited, and examples thereof include the above-mentioned substituents that can be employed as R¹ and R². Among these, an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxyl group is preferable, and an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxyl group is more preferable.

Further, B⁵, B⁶, B⁷, and B⁸ have the same meaning as the above B¹, B², B³, and B⁴, respectively.

The substituent possessed by the carbon atom that can be employed as B¹ to B¹ may further have a substituent. Examples of the substituent which may be further contained include the substituent X.

Examples of the substituent that can be possessed by the carbon atom that can be employed as B¹, B⁴, B⁵, and B⁸ still more preferably include an alkyl group, an alkoxy group, a hydroxyl group, an amide group, a sulfonylamide group, or a carbamoyl group, and particularly preferably an alkyl group, an alkoxy group, a hydroxyl group, an amide group, or a sulfonylamide group, where a hydroxyl group, an amide group, or a sulfonylamide group is most preferable.

It is still more preferable that the substituent that can be possessed by the carbon atom that can be employed as B², B³, B⁶, and B⁷ is an alkyl group, an alkoxy group, an alkoxycarbonyl group, an acyl group, an amino group, a cyano group, a nitro group, or a halogen atom, and it is particularly preferable that the substituent of any one of them is an electron withdrawing group (for example, an alkoxycarbonyl group, an acyl group, a cyano group, a nitro group, or a halogen atom).

In General Formula (14), R¹ and R² may be bonded to each other to form a ring, and R¹ or R² and the substituent contained in B² or B³ may be bonded to each other to form a ring. In addition, R⁴¹ and R⁴² may be bonded to each other to form a ring, and R⁴¹ or R⁴² and the substituent contained in B⁶ or B⁷ may be bonded to each other to form a ring.

In the above description, the ring to be formed is preferably a heterocyclic ring or a heteroaryl ring, and it is preferably a 5-membered ring or a 6-membered ring although the size of the ring to be formed is not particularly limited. Further, the number of rings to be formed is not particularly limited, and it may be one or may be two or more. Examples of an aspect in which two or more rings are formed include an aspect in which, for example, the substituents of R¹ and B² and the substituents of R² and B³ are bonded to each other respectively to form two rings.

Specific examples of the coloring agent represented by General Formula (1) among the dyes D are shown below. However, the present invention is not limited thereto.

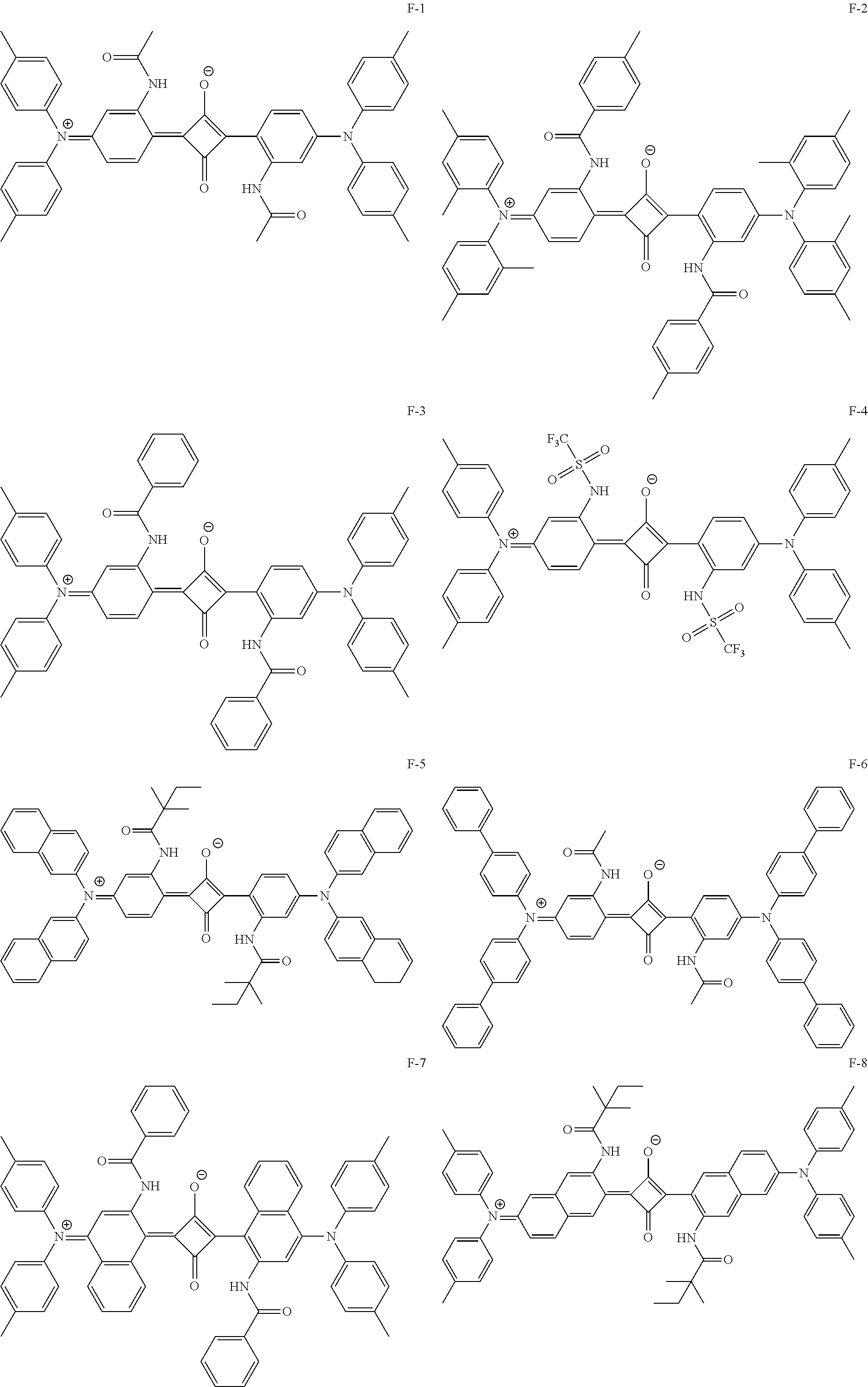

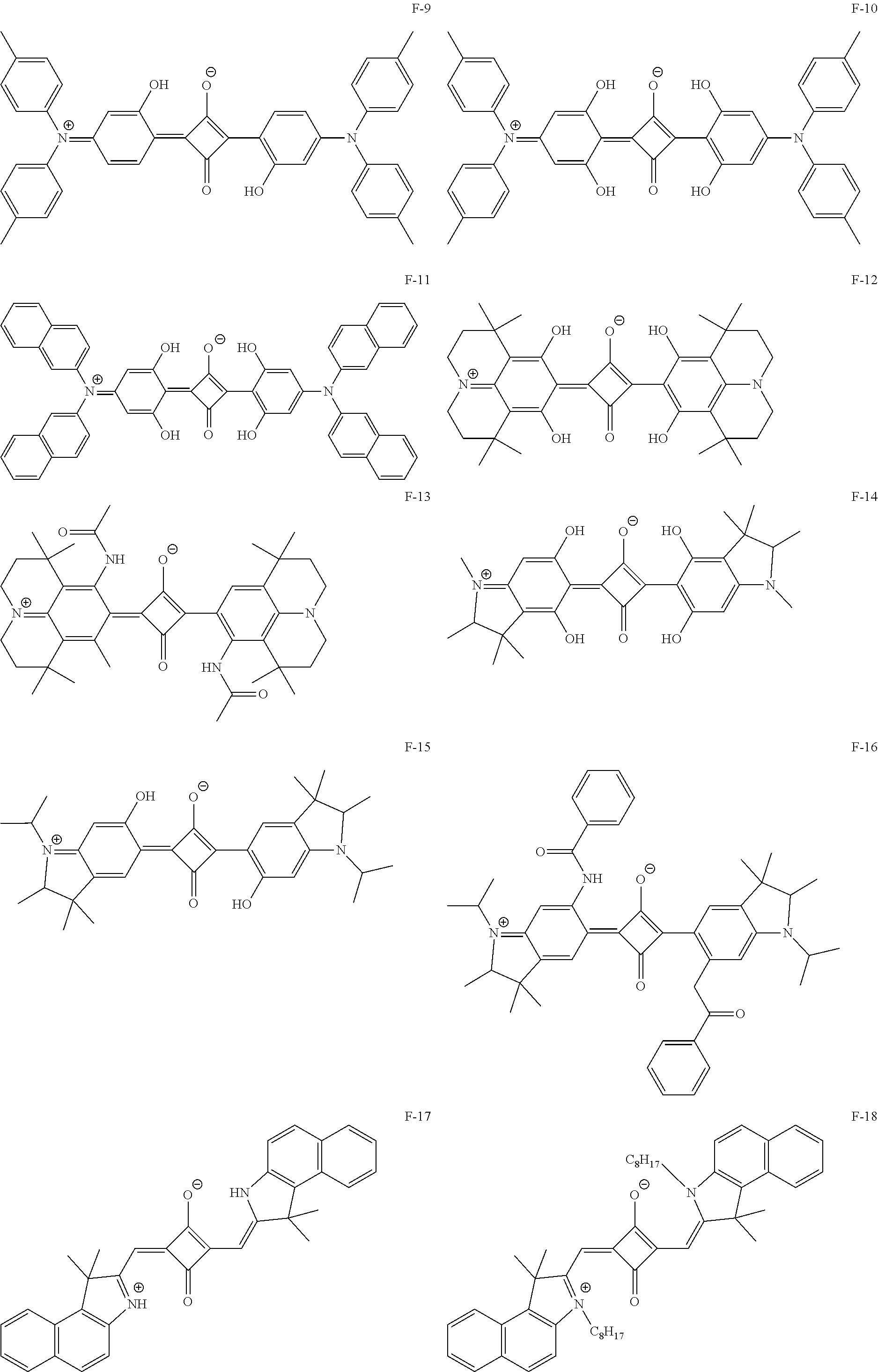

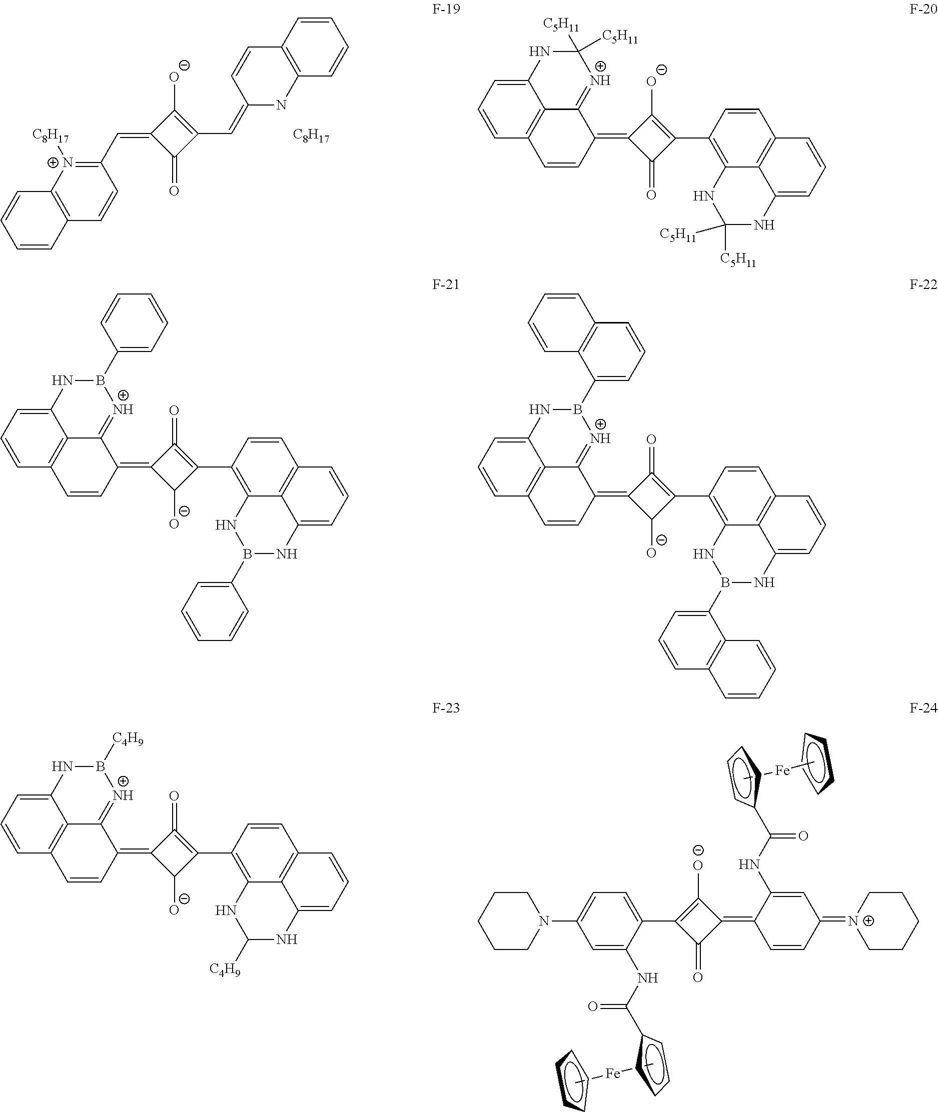

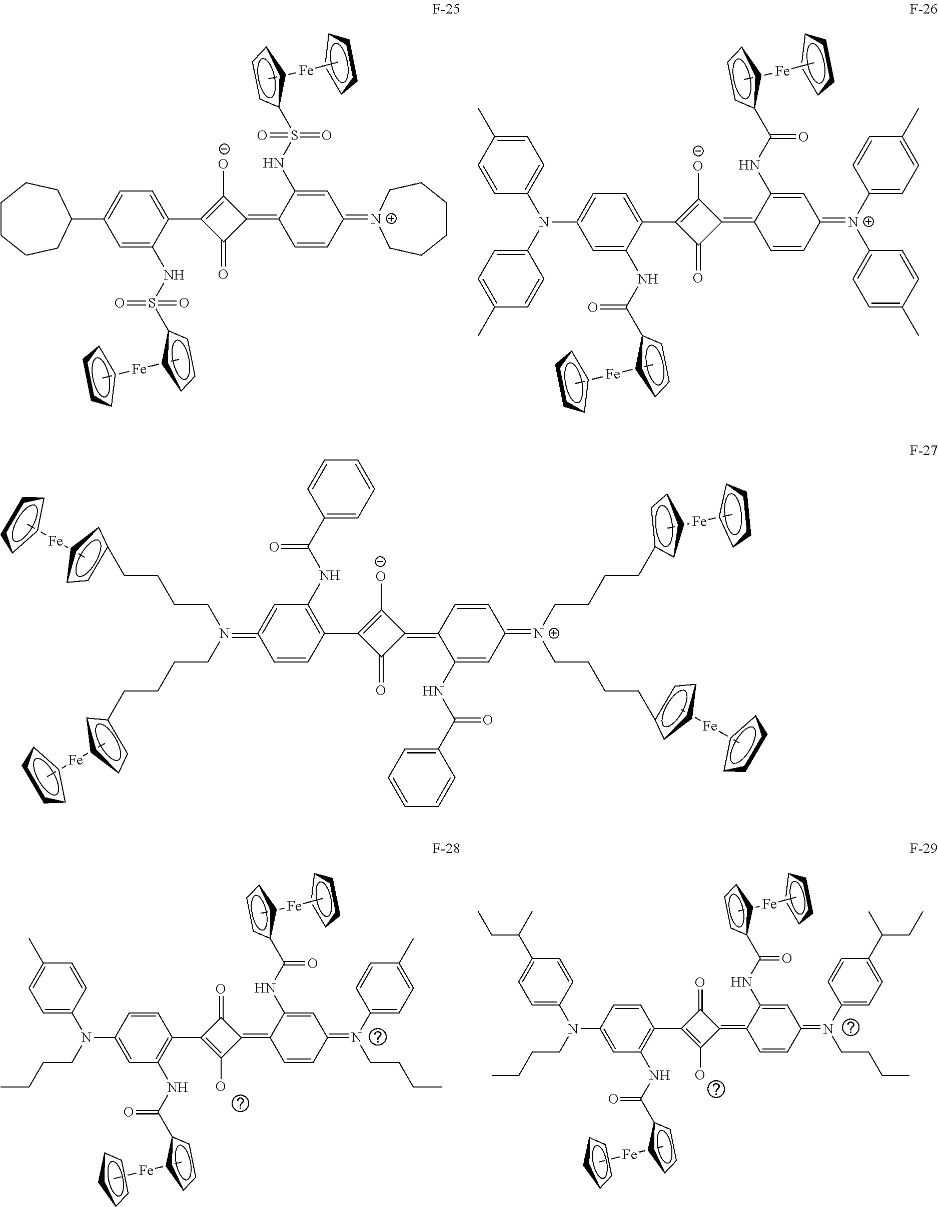

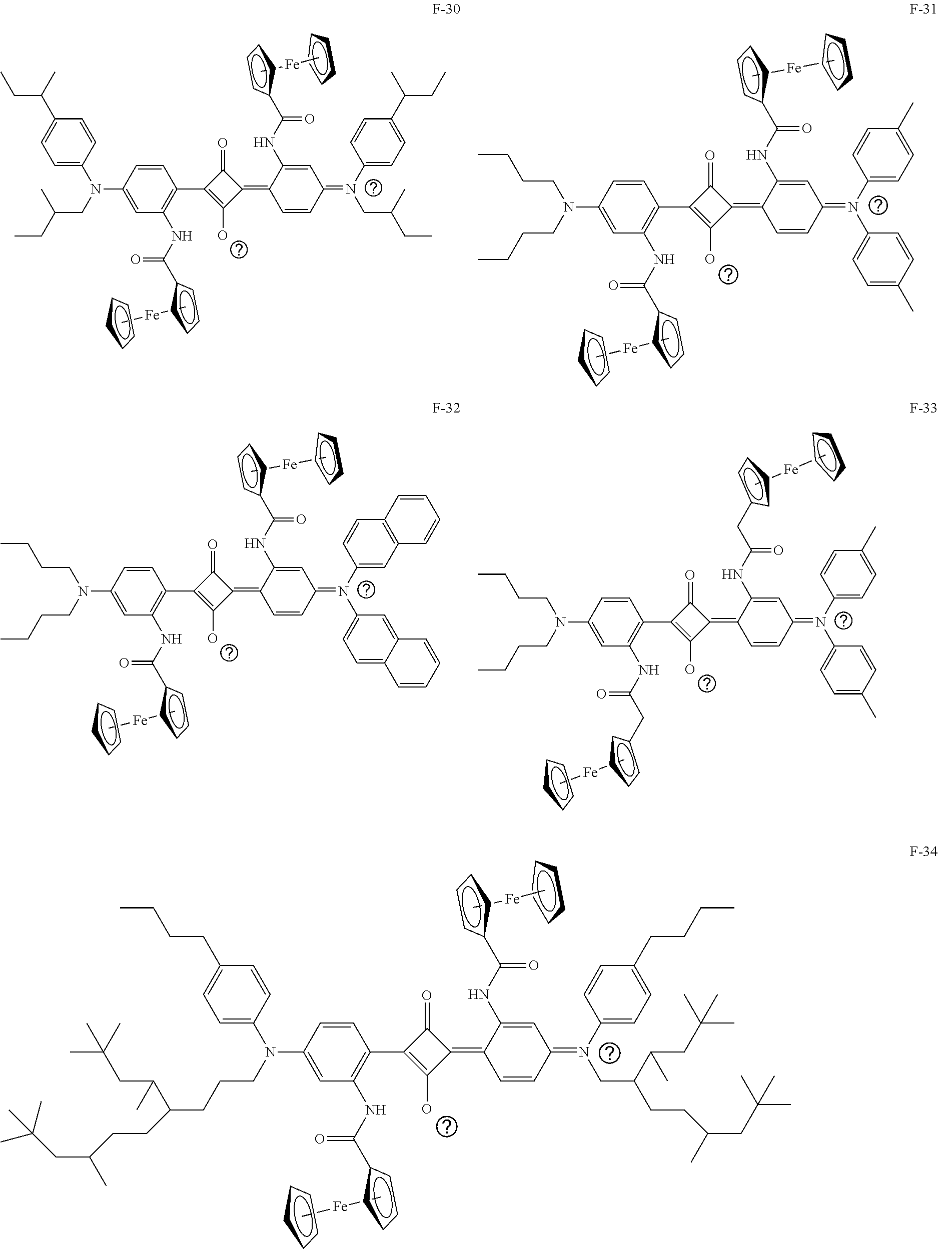

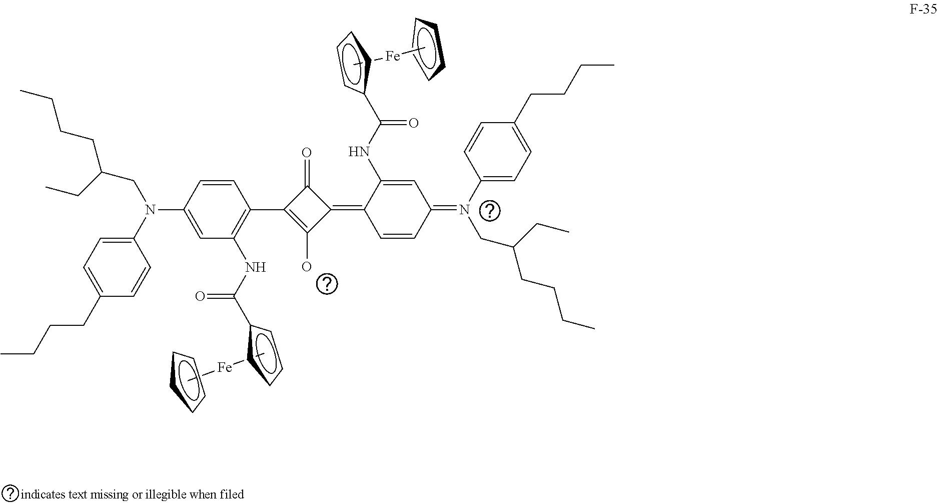

A total content of the dyes A to D in the wavelength selective absorption filter according to the embodiment of the present invention is preferably 1.0% by mass or more, more preferably 1.5% by mass or more, still more preferably 2.0% by mass or more, particularly preferably 2.5% by mass or more, and especially preferably 3.0% by mass or more. In a case where the total content of the dyes A to D in the wavelength selective absorption filter is equal to or more than the above-mentioned preferable lower limit value, a favorable antireflection effect can be obtained.

In addition, the total content of the dyes A to D in the wavelength selective absorption filter is generally 50% by mass or less, preferably 40% by mass or less, more preferably 30% by mass or less, still more preferably 15% by mass or less, and particularly preferably 10% by mass or less.

That is, the total content of the dyes A to D in the wavelength selective absorption filter according to the embodiment of the present invention is preferably 1.0% to 50% by mass, more preferably 1.5% to 40% by mass, still more preferably 2.0% to 30% by mass, particularly preferably 2.5% to 15% by mass, and especially preferably 3.0% to 10% by mass.

With regard to contents of each dye in the wavelength selective absorption filter according to the embodiment of the present invention, a content of the dye B is preferably 0.01% to 45% by mass, more preferably 0.1% to 30% by mass, and still more preferably 0.1% to 10% by mass. A content of the dye C is preferably 0.01% to 45% by mass, more preferably 0.1% to 30% by mass, and still more preferably 0.5% to 15% by mass. A content of the dye D is preferably 0.05% to 50% by mass, more preferably 0.2% to 20% by mass, and still more preferably 0.2% to 10% by mass.

In a case where the wavelength selective absorption filter according to the embodiment of the present invention contains the dye A, a content of the dye A in the wavelength selective absorption filter is preferably 0.01% to 45% by mass, more preferably 0.1% to 30% by mass, and still more preferably 0.1% to 10% by mass.

A content ratio of individual dyes A to D in the wavelength selective absorption filter is preferably dye A:dye B:dye C:dye D=0 to 5:0.1 to 2:1:0.1 to 5, and more preferably 0 to 2:0.1 to 1:1:0.1 to 2 in terms of a mass ratio.

It is noted that in a case where at least one of the dye B or the dye C is the quencher-embedded coloring agent, a content of the quencher-embedded coloring agent in a light absorption filter according to the embodiment of the present invention is preferably 0.1% by mass or more from the viewpoint of the antireflection effect. The upper limit value thereof is preferably 45% by mass or less. That is, it is preferably 0.1 to 45 mass % in the wavelength selective absorption filter according to the embodiment of the present invention.

### <Resin>

The resin contained in the wavelength selective absorption filter according to the embodiment of the present invention (hereinafter, also referred to as “resin used in the present invention” and “matrix resin”) is not particularly limited, as long as the resin can disperse (preferably dissolve) a dye including the dyes B to D, can satisfy the suppression of external light reflection and the suppression of the decrease in brightness, and can maintain the original tint of the image of the OLED display device at an excellent level. In a case where at least one of the dye B or the dye C is a squaraine-based coloring agent represented by General Formula (1), the matrix resin is preferably a low-polarity matrix resin in which the squaraine-based coloring agent can exhibit sharper absorption. In a case where the squaraine-based coloring agent exhibits the sharper absorption, Relational Expressions (I) and (II) can be satisfied at a preferable level, and the original tint of the image of the OLED display device can be maintained at a more excellent level. Here, in the low-polarity, it is preferable that an fd value defined by Relational Expression α described in paragraphs [0130] of WO2022/138925A is 0.50 or more.

fd=δd/(δd+δp+δh) Relational Expression α:

In Relational Expression α, δd, δp, and δh respectively indicate a term corresponding to a London dispersion force, a term corresponding to a dipole-dipole force, and a term corresponding to a hydrogen bonding force with respect to a solubility parameter δt calculated according to the Hoy method. A specific calculation method is as described in paragraphs [0131] to [0133] of WO2022/138925A. That is, fd represents a ratio of δd to the sum of δd, δp, and δh.

By setting the fd value to 0.50 or more, a sharper absorption waveform can be easily obtained.

Further, in a case where the wavelength selective absorption filter contains two or more matrix resins, the fd value is calculated as follows.

fd=Σ(wi·fdi)

Here, wi represents the mass fraction of the i-th matrix resin, and fdi represents the fd value of the i-th matrix resin.

In addition, in a case where the matrix resin is a resin exhibiting a certain hydrophobicity, a moisture content of the wavelength selective absorption filter according to the embodiment of the present invention can be set to a low moisture content, for example, 0.5% or less, and the light resistance of the wavelength selective absorption filter is improved, which is preferable. The resin may contain a predetermined conventional component in addition to a polymer. However, the fd of the matrix resin is a calculated value for the polymer constituting the matrix resin.

Preferable examples of the resin used in the present invention include a polystyrene resin and a cyclic polyolefin resin, and a cyclic polyolefin resin is more preferable. Usually, the fd value of the polystyrene resin is 0.45 to 0.60, and the fd value of the cyclic polyolefin resin is 0.45 to 0.70. As described above, it is preferable to use the resin having a fd value of 0.50 or more.

Further, for example, in addition to these preferable resins, it is also preferable to use a resin component, that imparts functionality to the wavelength selective absorption filter, such as an extensible resin component and a peelability control resin component, which will be described later. That is, in the present invention, the matrix resin is used in the meaning of including the extensible resin component and the peelability control resin component in addition to the above-mentioned resins.

It is preferable that the resin used in the present invention includes a cyclic polyolefin resin, from the viewpoint of sharpening the absorption waveform of the coloring agent.

### (Polystyrene Resin)

The polystyrene contained in the polystyrene resin means a polymer containing a styrene component. The polystyrene preferably contains 50% by mass or more of the styrene component. The wavelength selective absorption filter according to the embodiment of the present invention may contain one type of polystyrene or two or more types of polystyrene. Here, the styrene component is a structural unit derived from a monomer having a styrene skeleton in the structure thereof.

The polystyrene more preferably contains 70% by mass or more of the styrene component, and still more preferably 85% by mass or more of the styrene component, in terms of controlling the photoelastic modulus and the hygroscopicity to values within a preferable range as the wavelength selective absorption filter. It is also preferable that the polystyrene is composed of only a styrene component.

Among polystyrenes, as the polystyrenes composed of only styrene components, a homopolymer of a styrene compound and a copolymer of two or more types of a styrene compound are exemplified. Here, the styrene compound is a compound having a styrene skeleton in the structure thereof, and is meant to include, in addition to styrene, a compound in which a substituent is introduced within a range where an ethylenically unsaturated bond of styrene can act as a reactive (polymerizable) group.

Specific examples of the styrene compound include, for example, styrene; alkylstyrene such as α-methylstyrene, o-methylstyrene, m-methylstyrene, p-methylstyrene, 3,5-dimethylstyrene, 2,4-dimethylstyrene, o-ethylstyrene, p-ethylstyrene, and tert-butyl styrene; and substituted styrene having a hydroxyl group, an alkoxy group, a carboxy group, or a halogen atom introduced into the benzene nucleus of styrene such as hydroxystyrene, tert-butoxy styrene, vinyl benzoic acid, o-chlorostyrene, and p-chlorostyrene. Among these, from the viewpoint of easy procurement, material costs, and the like, the polystyrene used in the present invention is preferably a homopolymer of styrene (that is, polystyrene).

The constituent components other than the styrene component that can be contained in the polystyrene are not particularly limited. That is, the polystyrene may be a styrene-diene copolymer, a styrene-polymerizable unsaturated carboxylic acid ester copolymer, or the like. In addition, it is also possible to use a mixture of polystyrene and synthetic rubber (for example, polybutadiene and polyisoprene). Further, high impact polystyrene (HIPS) obtained by graft-polymerizing styrene to synthetic rubber is also preferable. Further, a polystyrene obtained by dispersing a rubber-like elastic body in a continuous phase of a polymer including a styrene component (for example, a copolymer of a styrene component and a (meth)acrylate ester component), and graft-polymerizing the copolymer with the rubber-like elastic body (referred to as graft type high impact polystyrene “graft HIPS”) is also preferable. Furthermore, a so-called styrene-based elastomer can also be suitably used.

In addition, the polystyrene may be hydrogenated (may be a hydrogenated polystyrene). The hydrogenated polystyrene is not particularly limited, and it is preferably a hydrogenated styrene-diene-based copolymer such as a hydrogenated styrene-butadiene-styrene block copolymer (SEBS) obtained by hydrogenating a styrene-butadiene-styrene block copolymer (SBS) or hydrogenated styrene-isoprene-styrene block copolymer (SEPS) obtained by hydrogenating a styrene-isoprene-styrene block copolymer (SIS). Only one of the hydrogenated polystyrenes may be used, or two or more thereof may be used.

In addition, the polystyrene may be modified polystyrene. The modified polystyrene is not particularly limited, and examples thereof include polystyrene having a reactive group such as a polar group introduced therein. Specific examples thereof preferably include acid-modified polystyrene such as maleic acid-modified and epoxy-modified polystyrene.

As the polystyrene, a plurality of types of polystyrene having different compositions, molecular weights, and the like can be used in combination.

The polystyrene-based resin can be obtained using a conventional method such as anion, bulk, suspension, emulsification, or a solution polymerization method. In addition, in the polystyrene, at least a part of the unsaturated double bond of the benzene ring of the conjugated diene and the styrene monomer may be hydrogenated. The hydrogenation rate can be measured by a nuclear magnetic resonance apparatus (NMR).

As the polystyrene resin, a commercially available product may be used, and examples thereof include “CLEAREN 530L”, “CLEAREN 730L” manufactured by Denka Company Limited, “TUFPRENE 1265”, “ASAPRENE T411” manufactured by Asahi Kasei Corporation, “KRATON D1102A”, “KRATON D1116A” manufactured by Kraton Corporation, “STYROLUX S”, “STYROLUX T” manufactured by INEOS Styrolution Group GmbH, “ASAFLEX 840”, “ASAFLEX 860” manufactured by Asahi Kasei Corporation (all of which is SBS), “679”, “HF77”, “SGP-10” manufactured by PS Japan Corporation, “DICSTYRENE XC-515”, “DICSTYRENE XC-535” manufactured by DIC Corporation (all of which is GPPS), “475D”, “H0103”, “HT478” manufactured by PS Japan Corporation, and “DICSTYRENE GH-8300-5” manufactured by DIC Corporation (all of which is HIPS). Examples of the hydrogenated polystyrene-based resin include “TUFTEC H Series” manufactured by Asahi Kasei Corporation, “KRATON G Series” manufactured by Shell Japan Limited (all of which is SEBS), “DYNARON” manufactured by JSR Corporation (hydrogenated styrene-butadiene random copolymer), and “SEPTON” manufactured by Kuraray Co., Ltd.(SEPS). In addition, examples of a modified polystyrene-based resin include “TUFTEC M Series” manufactured by Asahi Kasei Corporation, “EPOFRIEND” manufactured by Daicel Corporation, “polar group-modified DYNARON” manufactured by JSR Corporation, and “RESEDA” manufactured by Toagosei Co., Ltd.

The wavelength selective absorption filter according to the embodiment of the present invention preferably contains a polyphenylene ether resin in addition to the polystyrene resin. By containing the polystyrene resin and the polyphenylene ether resin together, the toughness of the wavelength selective absorption filter can be improved, and the occurrence of defects such as cracks can be suppressed even in a harsh environment such as high temperature and high humidity.

As the polyphenylene ether resin, ZYLON S201A, ZYLON S202A, ZYLON S203A, and the like manufactured by Asahi Kasei Corporation can be preferably used. In addition, a resin in which the polystyrene resin and the polyphenylene ether resin are mixed in advance may also be used. As the mixed resin of the polystyrene resin and the polyphenylene ether resin, for example, ZYLON 1002H, ZYLON 1000H, ZYLON 600H, ZYLON 500H, ZYLON 400H, ZYLON 300H, ZYLON 200H, and the like manufactured by Asahi Kasei Corporation can be preferably used.

In a case where the polystyrene resin and the polyphenylene ether resin are contained in the wavelength selective absorption filter according to the embodiment of the present invention, the mass ratio of both resins is preferably 99/1 to 50/50, more preferably 98/2 to 60/40, and still more preferably 95/5 to 70/30, for the polystyrene resin/polyphenylene ether resin. By setting the formulation ratio of the polyphenylene ether resin in the above-mentioned preferable range, the wavelength selective absorption filter can have sufficient toughness, and the solvent can be appropriately volatilized in a case where a solution film is formed.

### (Cyclic Polyolefin Resin)

The cyclic olefin compound forming the cyclic polyolefin contained in the cyclic polyolefin resin is not particularly limited as long as the compound has a ring structure including a carbon-carbon double bond, and examples thereof include norbornene compounds and monocyclic olefin compounds, cyclic conjugated diene compounds, vinyl alicyclic hydrocarbon compounds, which are not norbornene compounds, and the like.

Examples of the cyclic polyolefin include (1) polymers including a structural unit derived from a norbornene compound, (2) polymers including a structural unit derived from a monocyclic olefin compound other than the norbornene compound, (3) polymers including a structural unit derived from a cyclic conjugated diene compound, (4) polymers including a structural unit derived from a vinyl alicyclic hydrocarbon compound, hydrides of polymers including a structural unit derived from each of the compounds (1) to (4), and the like. In the present invention, ring-opening polymers of the respective compounds are included in the polymers including a structural unit derived from a norbornene compound and the polymers including a structural unit derived from a monocyclic olefin compound.

The cyclic polyolefin is not particularly limited, but a polymer having a structural unit derived from a norbornene compound, which is represented by General Formula (A-II) or (A-III), is preferable. The polymer having the structural unit represented by General Formula (A-II) is an addition polymer of a norbornene compound, and the polymer having the structural unit represented by General Formula (A-III) is a ring-opening polymer of a norbornene compound.

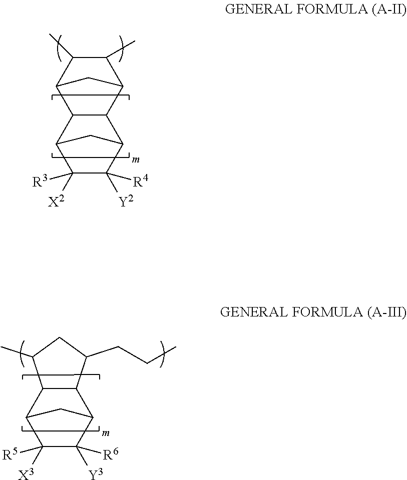

In General Formulae (A-II) and (A-III), m is an integer of 0 to 4, and preferably 0 or 1.

In General Formulae (A-II) and (A-III), R³ to R⁶ each independently represent a hydrogen atom or a hydrocarbon group having 1 to 10 carbon atoms.

In the present invention, a hydrocarbon group is not particularly limited as long as the hydrocarbon group is a group consisting of a carbon atom and a hydrogen atom, and examples thereof include an alkyl group, an alkenyl group, an alkynyl group, and an aryl group (an aromatic hydrocarbon group). Among these, an alkyl group or an aryl group is preferable.

In General Formula (A-II) or (A-III), X² and X³, and Y² and Y³ each independently represent a hydrogen atom, a hydrocarbon group having 1 to 10 carbon atoms, a halogen atom, a hydrocarbon group having 1 to 10 carbon atoms which is substituted by a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ or —(CH₂)ₙW, or (—CO)₂O or (—CO)₂NR¹⁵ which is formed by X² and Y² or X³ and Y³ bonded to each other.

Here, R¹¹ to R¹⁵ each independently represent a hydrogen atom or a hydrocarbon group having 1 to 20 carbon atoms, Z represents a hydrocarbon group or a hydrocarbon group substituted by halogen, W represents Si(R¹⁶)ₚD₍₃₋ₚ₎ (R¹⁶ represents a hydrocarbon group having 1 to 10 carbon atoms, and D represents a halogen atom, —OCOR¹⁷, or —OR¹⁷ (R¹⁷ represents a hydrocarbon group having 1 to 10 carbon atoms), and p is an integer of 0 to 3.). n is an integer of 0 to 10, preferably 0 to 8, and more preferably 0 to 6.

In General Formulae (A-II) and (A-III), R³ to R⁶ are each preferably a hydrogen atom or —CH₃, and, from the viewpoint of moisture permeability, more preferably a hydrogen atom.

X² and X³ are each preferably a hydrogen atom, —CH₃, or —C₂H₅ and more preferably a hydrogen atom in terms of moisture permeability.

Y² and Y³ are each preferably a hydrogen atom, a halogen atom (particularly a chlorine atom), or —(CH₂)ₙCOOR¹¹ (particularly —COOCH₃) and more preferably a hydrogen atom in terms of moisture permeability. Other groups are appropriately selected.

The polymer having the structural unit represented by General Formula (A-II) or (A-III) may further include at least one or more structural units represented by General Formula (A-I).

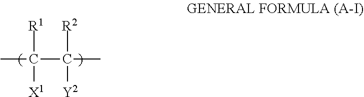

In General Formula (A-I), R¹ and R² each independently represent a hydrogen atom or a hydrocarbon group having 1 to 10 carbon atoms, and X¹ and Y¹ each independently represent a hydrogen atom, a hydrocarbon group having 1 to 10 carbon atoms, a halogen atom, a hydrocarbon group having 1 to 10 carbon atoms which is substituted by a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ, —(CH₂)ₙW, or (—CO)₂O or (—CO)₂NR¹⁵ which is formed by X¹ and Y¹ bonded to each other.

Here, R¹¹ to R¹⁵ each independently represent a hydrogen atom or a hydrocarbon group having 1 to 20 carbon atoms, Z represents a hydrocarbon group or a hydrocarbon group substituted by halogen, W represents Si(R¹⁶)ₚD₍₃₋ₚ₎ (R¹⁶ represents a hydrocarbon group having 1 to 10 carbon atoms, and D represents a halogen atom, —OCOR¹⁷, or —OR¹⁷ (R¹⁷ represents a hydrocarbon group having 1 to 10 carbon atoms), and p is an integer of 0 to 3.). n represents an integer of 0 to 10.

From the viewpoint of adhesiveness, the content of the structural unit derived from the norbornene compound in the cyclic polyolefin having the structural unit represented by General Formula (A-II) or (A-III) is preferably 90% by mass or less, more preferably 30% to 85% by mass, still more preferably 50% to 79% by mass, and most preferably 60% to 75% by mass with respect to the total mass of the cyclic polyolefin. Here, the proportion of the structural unit derived from a norbornene compound represents the average value in the cyclic polyolefin.

The addition (co)polymer of a norbornene compound is described in JP1998-7732A (JP-H10-7732A), JP2002-504184A, US2004/229157A1A, and WO2004/070463A.

The polymer of a norbornene compound is obtained by the addition polymerization of norbornene compounds (for example, polycyclic unsaturated compounds of norbornene).

In addition, as the polymer of a norbornene compound, copolymers obtained by the addition copolymerization of, as necessary, a norbornene compound, olefin such as ethylene, propylene, and butene, conjugated diene such as butadiene and isoprene, unconjugated diene such as ethylidene norbornene, and an ethylenically unsaturated compound such as acrylonitrile, acrylic acid, methacrylic acid, maleic acid anhydride, acrylic acid ester, methacrylic acid ester, maleimide, vinyl acetate, and vinyl chloride are exemplified. Among these, a copolymer of a norbornene compound and ethylene is preferable.

Examples of the addition (co)polymers of a norbornene compound include APL8008T (Tg: 70° C.), APL6011T (Tg: 105° C.), APL6013T (Tg: 125° C.), and APL6015T (Tg: 145° C.), which are available from Mitsui Chemicals, Inc. under a product name of APEL and have glass transition temperatures (Tg) different from each other. In addition, pellets such as TOPAS8007, TOPAS6013, and TOPAS6015 are commercially available from Polyplastics Co., Ltd. Further, Appear 3000 is put on the market by Film Ferrania S.R.L.

As the polymer of the norbornene compound, commercially available products can be used. For example, polymers are put on the market by JSR Corporation under a product name of Arton G or Arton F, and polymers are put on the market by Zeon Corporation under a product name of Zeonor ZF14, ZF16, Zeonex 250, or Zeonex 280.

The hydride of a polymer of a norbornene compound can be synthesized by the addition polymerization or the metathesis ring-opening polymerization of a norbornene compound or the like and then the addition of hydrogen. The synthesis method is described in, for example, JP1989-240517A (JP-H1-240517A), JP1995-196736A (JP-H7-196736A), JP1985-26024A (JP-S60-26024A), JP1987-19801A (JP-S62-19801A), JP2003-159767A, JP2004-309979A, and the like.

The molecular weight of the cyclic polyolefin that is used in the present invention is appropriately selected depending on the intended use, and is a mass average molecular weight measured in terms of polyisoprene or polystyrene by the gel permeation chromatography of a cyclohexane solution (a toluene solution in a case where the polymer is not dissolved). The molecular weight is in a range of, usually, 5000 to 500000, preferably 8000 to 200000, and more preferably 10000 to 100000. A polymer having a molecular weight in the above-mentioned range is capable of satisfying both the mechanical strength of a molded body and the molding workability of compacts at a high level in a well-balanced manner.

In the wavelength selective absorption filter according to the embodiment of the present invention, the content of the matrix resin is preferably 5% by mass or more, more preferably 20% by mass or more, still more preferably 50% by mass or more, particularly preferably 70% by mass or more, more particularly preferably 80% by mass, and most preferably 90% by mass or more.

The content of the matrix resin in the wavelength selective absorption filter according to the embodiment of the present invention is usually 99.90% by mass or less, and preferably 99.85% by mass or less. That is, the content of the matrix resin is practically preferably 5% to 99.90% by mass, more preferably 20% to 99.90% by mass, still more preferably 50% to 99.90% by mass, particularly preferably 70% to 99.90% by mass, more particularly preferably 80% to 99.90% by mass, and most preferably 90% to 99.85% by mass.

The cyclic polyolefin contained in the wavelength selective absorption filter may be two or more types, and polymers in which at least one of a compositional ratio or a molecular weight is different may be used in combination. In this case, the total content of the respective polymers is in the range.

### (Extensible Resin Component)

The wavelength selective absorption filter according to the embodiment of the present invention can appropriately select and contain a component exhibiting extensibility (also referred to as an extensible resin component) as a resin component. Specific examples thereof can include an acrylonitrile-butadiene-styrene resin (ABS resin), a styrene-butadiene resin (SB resin), an isoprene resin, a butadiene resin, a polyether-urethane resin, a silicone resin, and the like. Further, these resins may be further hydrogenated as appropriate.

As the extensible resin component, it is preferable to use the ABS resin or the SB resin, and it is more preferable to use the SB resin.

As the SB resin, for example, a commercially available one can be used. As such commercial products, TR2000, TR2003, and TR2250 (all, product name, manufactured by JSR Corporation), CLEAREN 210M, 220M, and 730V (all, product name, manufactured by Denka Corporation), Asaflex 800S, 805, 810, 825, 830, and 840 (all, product name, manufactured by Asahi Kasei Corporation), EPOREX SB2400, SB2610, and SB2710 (all, product name, Sumitomo Chemical Co., Ltd.), and the like can be exemplified.

The wavelength selective absorption filter according to the embodiment of the present invention preferably contains an extensible resin component in the matrix resin in an amount of 15% to 95% by mass, more preferably 20% to 50% by mass, and still more preferably 25% to 45% by mass.

As the extensible resin component, in a case where a sample having an aspect with a thickness of 30 μm and a width of 10 mm is prepared by using the extensible resin component alone and the breaking elongation at 25° C. is measured in accordance with JIS 7127, a component having the breaking elongation of 10% or more is preferable, and a component having the breaking elongation of 20% or more is more preferable.

### (Peelability Control Resin Component)

The wavelength selective absorption filter according to the embodiment of the present invention can preferably contain a component that controls the peelability (peelability control resin component), as a resin component, in a case where the wavelength selective absorption filter is prepared by a method including a step of peeling the wavelength selective absorption filter from a release film, among manufacturing methods for the wavelength selective absorption filter according to the embodiment of the present invention described later. By controlling the peelability of the wavelength selective absorption filter from the release film, it is possible to prevent a peeling mark from being left on the wavelength selective absorption filter after peeling, and it is possible to cope with various processing speeds in the peeling step. As a result, a preferable effect can be obtained for improving the quality and productivity of the wavelength selective absorption filter.

The peelability control resin component is not particularly limited and can be appropriately selected depending on the type of the release film. As will be described later, in a case where a polyester-based polymer film is used as the release film, the peelability control resin component is suitably, for example, a polyester resin (also referred to as a polyester-based additive), and in a case where a cellulose-based polymer film is used as the release film, as the peelability control resin component, for example, a styrene-based elastomer is also suitably used.

The polyester-based additive can be obtained by a conventional method such as a dehydration condensation reaction of a polyhydric basic acid and a polyhydric alcohol and an addition of a dibasic anhydride to a polyhydric alcohol and a dehydration condensation reaction, and a polycondensation ester formed from a dibasic acid and a diol is preferable.

The mass average molecular weight (Mw) of the polyester-based additive is preferably 500 to 50,000, more preferably 750 to 40,000, and still more preferably 2,000 to 30,000.

In a case where the mass average molecular weight of the polyester-based additive is the above-mentioned preferable lower limit value or more, it is preferable from the viewpoint of brittleness and moisture-heat resistance, and in a case where the mass average molecular weight is the above-mentioned preferable upper limit value or less, it is preferable from the viewpoint of compatibility with the resin.

The mass average molecular weight of the polyester-based additive is a value of the mass average molecular weight (Mw) in terms of standard polystyrene measured under the following conditions. The molecular weight distribution (Mw/Mn) can also be measured under the same conditions. Mn is a standard polystyrene-equivalent number average molecular weight.
GPC: Gel permeation chromatograph device (HLC-8220GPC manufactured by Tosoh Corporation,
column: Guard column HXL-H manufactured by Tosoh Corporation, TSK gel G7000HXL, TSK gel GMHXL 2 pieces, TSK gel G2000HXL are connected in sequence,
eluent: tetrahydrofuran,
flow velocity: 1 mL/min,
sample concentration: 0.7-0.8% by mass,
sample injection volume: 70 μL,
measurement temperature: 40° C.,
detector: differential refractometer (RI) meter (40° C.), and
standard substance: TSK standard polystyrene manufactured by Tosoh Corporation)

With regard to the polyester-based additive and the styrene-based elastomer, each of descriptions related to the polyester-based additive and the styrene-based elastomer described in paragraphs [0164] to [0175] of WO2022/138925A can be applied.

The content of the peelability control resin component in the wavelength selective absorption filter according to the embodiment of the present invention is preferably 0.05% by mass or more, and more preferably 0.1% by mass or more in the matrix resin. In addition, an upper limit value thereof is preferably 25% by mass or less, more preferably 20% by mass or less, and still more preferably 15% by mass or less. From the viewpoint of obtaining appropriate adhesiveness, the above-mentioned preferable range is preferable. That is, in the wavelength selective absorption filter according to the embodiment of the present invention, the content of the peelability control resin component in the matrix resin is preferably 0.05% to 25% by mass, more preferably 0.1% to 20% by mass, and still more preferably 0.1% to 15% by mass.

### <Other Components>

The wavelength selective absorption filter according to the embodiment of the present invention may contain an antifading agent, an association inhibitor, a matting agent, a leveling (surfactant) agent, or the like in addition to the dye containing the dyes B to D and the matrix resin.

### (Antifading Agent)

In order to prevent fading of the dye containing the dyes B to D, the wavelength selective absorption filter according to the embodiment of the present invention preferably contains an antifading agent. As the discoloration preventer used in the present invention, antioxidants described in paragraphs [0143] to [0165] of WO2015/005398A, radical scavengers described in paragraphs [0166] to [0199] of WO2015/005398A, and deterioration inhibitors described in paragraphs [0205] and [0206] of WO2015/005398A are can be used.

The compound represented by General Formula (IV) below can be preferably used as the antifading agent.

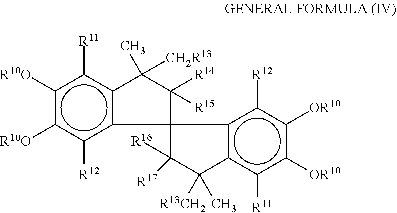

In Formula (IV), R¹⁰ represents an alkyl group, an alkenyl group, an aryl group, a heterocyclic group, or a group represented by R¹⁸ CO—, R¹⁹SO₂—, or R²⁰NHCO—. Here, R¹⁸, R¹⁹, and R²⁰ each independently represent an alkyl group, an alkenyl group, an aryl group, or a heterocyclic group. R¹¹ and R¹² each independently represent a hydrogen atom, a halogen atom, an alkyl group, an alkenyl group, an alkoxy group, or an alkenyloxy group, and R¹³, R¹⁴, R¹⁵, R¹⁶, and R¹⁷ each independently represent a hydrogen atom, an alkyl group, an alkenyl group, or an aryl group.

However, the alkyl group in R¹⁰ to R²⁰ includes an aralkyl group.

The compound represented by General Formula (IV) is the same as the compound represented by General Formula (IV) described in paragraphs [0215] to [0221] of WO2021/221122A. Therefore, for the description of each substituent in General Formula (IV) and the specific examples of the compound represented by General Formula (IV), the description of paragraphs [0217] to [0221] of WO2021/221122A can be applied as it is.

As the antifading agent, the compound represented by General Formula [III] below can also be preferably used.

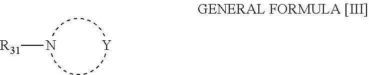

In General Formula [III], R₃₁ represents an aliphatic group or an aromatic group, and Y represents a group of non-metal atoms necessary for forming a 5- to 7-membered ring with a nitrogen atom.

The compound represented by General Formula [III] is the same as the compound represented by General Formula [III] described in paragraphs [0223] to [0227] of WO2021/221122A. Therefore, for the description of each substituent in General Formula [III] and the specific examples of the compound represented by General Formula [III], the description of paragraphs [0225] to [0227] of WO2021/221122A can be applied as it is.

In addition, in addition to the specific examples, specific examples of the compound represented by General Formula [III] above can include exemplary compounds B-1 to B-65 described on pages 8 to 11 of JP1990-167543A (JP-H2-167543A), and exemplary compounds (1) to (120) described on pages 4 to 7 of JP1988-95439A (JP-S63-95439A).

The content of the antifading agent in the wavelength selective absorption filter according to the embodiment of the present invention is preferably 0% to 20% by mass, more preferably 0% to 5% by mass, more preferably 0% to 3% by mass, and particularly preferably 0% to 2% by mass, in 100% by mass of the total mass of the wavelength selective absorption filter. By adding the antifading agent within the preferable ranges, the fastness of the dye (coloring agent) can be improved without causing side effects such as discoloration of the wavelength selective absorption filter.

### (Association Inhibitor)

In a case where the wavelength selective absorption filter according to the embodiment of the present invention interacts with the dyes containing the dyes B to D, since association of dye molecules in the wavelength selective absorption filter according to the embodiment of the present invention is suppressed and prevented, it is preferable to contain an association inhibitor. It is preferable that a compound, which exhibits a function of sharpening the absorption waveform of the dyes B to D contained in the wavelength selective absorption filter and improving the light fastness by an association inhibitor, contains the association inhibitor. As the association inhibitor used in the present invention, the association inhibitors described in paragraphs [0177] to [0228] of WO2022/138925A can be used.

The content of the association inhibitor in the wavelength selective absorption filter according to the embodiment of the present invention is preferably 0.1% to 30% by mass, more preferably 1% to 20% by mass, and still more preferably 2% to 15% by mass.

In the wavelength selective absorption filter according to the embodiment of the present invention, the association inhibitor is preferably contained at a proportion of 10 to 1,000 parts by mass, more preferably contained at a proportion of 20 to 700 parts by mass, and still more preferably contained at a proportion of 30 to 500 parts by mass, with respect to 100 parts by mass of the total contents of the dye including the dyes B to D.

### (Matting Agent)

It is preferable to add fine particles to the surface of the wavelength selective absorption filter according to the embodiment of the present invention in order to impart sliding properties and prevent blocking. As the fine particles, silica (silicon dioxide, SiO₂) whose surface is coated with a hydrophobic group and which is in the form of secondary particles is preferably used. The fine particles may use, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate. Examples of commercially available products of the fine particles include the R972 or NX90S (product name, both manufactured by Nippon Aerosil Co., Ltd.).

The fine particles function as a so-called matting agent, and the addition of the fine particles forms minute unevenness on the surface of the wavelength selective absorption filter according to the embodiment of the present invention. Due to the unevenness, even in a case where the wavelength selective absorption filters according to the embodiment of the present invention or the wavelength selective absorption filters according to the embodiment of the present invention and other films overlap each other, the filters do not stick to each other and sliding properties are ensured.

In a case where the wavelength selective absorption filter according to the embodiment of the present invention contains a matting agent as fine particles, and in the fine irregularities due to the protrusions in which fine particles protrude from the filter surface, there are 10⁴/mm² or more of protrusions having a height of 30 nm or more, the effect of improving sliding properties and blocking property is particularly large.

It is preferable to apply the matting agent fine particles particularly to the surface layer in order to improve the blocking properties and the sliding properties. As a method of applying the fine particles to the surface layer, there are means by multilayer casting and coating.

The content of the matting agent in the wavelength selective absorption filter according to the embodiment of the present invention is appropriately adjusted according to the purpose.

### (Leveling Agent)

A leveling agent (surfactant) can be appropriately mixed with the wavelength selective absorption filter according to the embodiment of the present invention. As the leveling agent, commonly used compounds can be used, and a fluorine-containing surfactant is particularly preferable. Specific examples thereof include the compounds described in paragraphs [0028] to [0056] of JP2001-330725A. In addition, as the commercially available product, MEGAFACE F (product name) series manufactured by DIC Corporation can also be used.

The content of the leveling agent in the wavelength selective absorption filter according to the embodiment of the present invention is appropriately adjusted according to the purpose.

The wavelength selective absorption filter according to the embodiment of the present invention may contain, in addition to the above components, a low-molecular plasticizer, an oligomer-based plasticizer, a retardation modifier, an ultraviolet absorber, a deterioration preventing agent, a peeling accelerator, an infrared absorber, an antioxidant, a filler, a compatibilizer, and the like.

### <Manufacturing Method of Wavelength Selective Absorption Filter>

The wavelength selective absorption filter according to the embodiment of the present invention can be prepared by a solution film forming method, a melt extrusion method, or a method of forming a coating layer on a base material film (release film) (coating method) according to a predetermined method, according to a conventional method, and stretching can also be appropriately combined. The wavelength selective absorption filter according to the embodiment of the present invention is preferably prepared by a coating method.

For the solution film-forming method and melt extrusion method described above, the descriptions regarding the solution film-forming method and the melt extrusion method in paragraphs [0268] to [0274] of WO2021/014973A can be applied as they are.

### (Coating Method)

In the coating method, a solution of a material of the wavelength selective absorption filter according to the embodiment of the present invention is applied to a release film to form a coating layer. A release agent or the like may be appropriately applied to the surface of the release film in advance in order to control the adhesiveness to the coating layer. The coating layer can be used by peeling off the release film after being laminated with another member through an adhesive layer in a later step. A predetermined adhesive can be appropriately used as the adhesive constituting the adhesive layer. The release film can be appropriately stretched together in a state in which the release film is coated with the solution of the material of the wavelength selective absorption filter according to the embodiment of the present invention or a state in which the coating layer is laminated.

The solvent used for the solution of the material of the wavelength selective absorption filter can be appropriately selected from the viewpoints that the material of the wavelength selective absorption filter can be dissolved or dispersed, and a uniform surface shape can be easily achieved during the coating step and drying step, liquid storability can be secured, an appropriate saturated vapor pressure is provided, and the like.

### —Addition of Dye (Coloring Agent)—

The timing of adding the dye to the material of the wavelength selective absorption filter is not particularly limited as long as the coloring agent is added at the time of film formation. For example, the dye may be added at a time point of synthesizing the matrix resin, or may be mixed with the material of the wavelength selective absorption filter when the coating liquid for the material of the wavelength selective absorption filter is prepared.

### —Release Film—

The release film used for forming the wavelength selective absorption filter by a coating method or the like preferably has a film thickness of 5 to 100 μm, more preferably 10 to 75 μm, and still more preferably 15 to 55 μm. In a case where the film thickness is equal to or more than the preferable lower limit value, sufficient mechanical strength is easily secured, and failures such as curling, wrinkling, and buckling are less likely to occur. In addition, in a case where the film thickness is equal to or less than the preferable upper limit value, in the storage of a multilayer film of the release film and the wavelength selective absorption filter according to the embodiment of the present invention, for example, in the aspect of a long roll, the surface pressure applied to the multilayer film is easily adjusted to be in an appropriate range, and adhesion defect is less likely to occur.

The surface energy of the release film is not particularly limited, and by adjusting the relationship between the surface energy of the material of the wavelength selective absorption filter or the coating solution and the surface energy of the surface of the release film on which the wavelength selective absorption filter is to be formed, the adhesive force between the wavelength selective absorption filter and the release film can be adjusted. In a case where the surface energy difference is reduced, the adhesive force tends to increase, and in a case where the surface energy difference is increased, the adhesive force tends to decrease, and thus the surface energy can be set appropriately.

The surface energy of the release film can be calculated from the contact angle value between water and methylene iodide using the method of Owens. For measurement of the contact angle, for example, DM901 (contact angle meter, manufactured by Kyowa Interface Science Co., Ltd.) can be used.

The surface energy of the surface of the release film on which the wavelength selective absorption filter is to be formed is preferably 41.0 to 48.0 mN/m and more preferably 42.0 to 48.0 mN/m. In a case where the surface energy is equal to or more than the preferable lower limit value, the evenness of the thickness of the wavelength selective absorption filter is increased. In a case where the surface energy is equal to or less than the preferable upper limit value, it is easy to control the peeling force of the wavelength selective absorption filter from the release film within an appropriate range.

The surface unevenness of the release film is not particularly limited, and depending on the relationship between the surface energy of the wavelength selective absorption filter surface, the hardness, and the surface unevenness, and the surface energy and hardness of the surface of the release film opposite to the side on which the wavelength selective absorption filter is formed, for example, in order to prevent adhesion defect in a case where the multilayer film of the release film and the wavelength selective absorption filter according to the embodiment of the present invention is stored in the aspect of a long roll, the surface unevenness of the release film can be adjusted. In a case where the surface unevenness is increased, adhesion defect tends to be suppressed, and in a case where the surface unevenness is reduced, the surface unevenness of the wavelength selective absorption filter tends to decrease and the haze of the wavelength selective absorption filter tends to be small. Thus, the surface unevenness can be set appropriately.

For such a release film, predetermined materials and films can be appropriately used. Specific examples of materials can include a polyester-based polymer (including polyethylene terephthalate-based film), an olefin-based polymer, a cyclo olefin-based polymer, a (meth)acrylic polymer, a cellulose-based polymer, and a polyamide-based polymer. In addition, a surface treatment can be appropriately performed for the purpose of adjusting the surface properties of the release film. For example, a corona treatment, a room temperature plasma treatment, a saponification treatment and the like can be performed to lower the surface energy, and a silicone treatment, a fluorine treatment, an olefin treatment and the like can be performed to raise the surface energy.

### —Peeling Force Between Wavelength Selective Absorption Filter and Release Film—

In a case where the wavelength selective absorption filter according to the embodiment of the present invention is formed by a coating method, the peeling force between the wavelength selective absorption filter and the release film can be controlled by adjusting the material of the wavelength selective absorption filter, the material of the release film, the internal strain of the wavelength selective absorption filter, and the like. The peeling force can be measured in, for example, a test of peeling off the release film in a direction of 90°, and the peeling force as measured at a speed of 300 mm/min is preferably 0.001 to 5 N/25 mm, more preferably 0.01 to 3 N/25 mm, and still more preferably 0.05 to 1 N/25 mm. In a case where the peeling force is equal to or greater than the above preferable lower limit value, peeling off the release film in a step other than the peeling step can be prevented, and in a case where the peeling force is equal to or smaller than the above preferable upper limit value, peeling failure in the peeling step (for example, zipping and cracking of the wavelength selective absorption filter) can be prevented.

### <Film Thickness of Wavelength Selective Absorption Filter>

The film thickness of the wavelength selective absorption filter according to the embodiment of the present invention is not particularly limited, and it is preferably 1 to 18 μm, more preferably 1 to 12 μm, and still more preferably 1 to 8 μm. In a case where the film thickness is equal to or smaller than the preferred upper limit value, the decrease in the degree of polarization due to the fluorescence emitted by a dye (a coloring agent) can be suppressed by adding the dye to the thin film at a high concentration. In addition, the effects of the quencher and the antifading agent are easily exhibited. On the other hand, in a case where the film thickness is equal to or more than the above preferable lower limit value, it is easy to maintain the evenness of the in-plane light absorbance.

In the present invention, the film thickness of 1 to 18 μm means that the thickness of the wavelength selective absorption filter is within a range of 1 to 18 μm even in a case where the thickness is measured at any portion. The same applies to the film thicknesses of 1 to 12 μm and 1 to 8 μm. The film thickness can be measured with an electronic micrometer manufactured by Anritsu Corporation.

### <Light Absorbance of Wavelength Selective Absorption Filter>

In the wavelength selective absorption filter according to the embodiment of the present invention, the light absorbance Ab (430) at a wavelength of 430 nm is preferably 0 or more and less than 3.0, more preferably 0.01 or more and less than 2.0, and still more preferably 0.05 or more and less than 1.0.

In addition, a light absorbance Ab (500) at a wavelength of 500 nm is preferably 0.05 or more and less than 2.1, more preferably 0.1 or more and less than 1.4, and still more preferably 0.1 or more and less than 1.05.

A light absorbance Ab (600) at a wavelength of 600 nm is preferably 0.1 or more and 3.0 or less, more preferably 0.2 or more and 2.0 or less, and still more preferably 0.3 or more and 1.5 or less.

A light absorbance Ab (700) at a wavelength of 700 nm is preferably 0.01 or more and 3.0 or less, more preferably 0.05 or more and 2.0 or less, and still more preferably more than 0.05 and 1.5 or less.

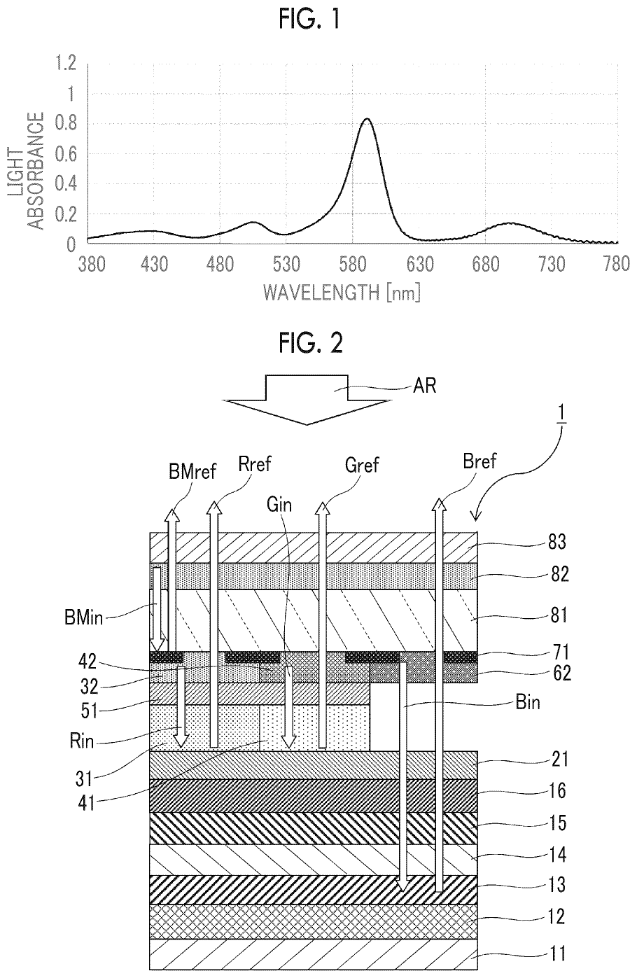

In an absorption spectrum of a No. 1 wavelength selective absorption filter produced in the example shown in FIG. 1 to be described later, the light absorbance at a wavelength of 430 nm is 0.08, the light absorbance at a wavelength of 500 nm is 0.13, the light absorbance at a wavelength of 600 nm is 0.60, and the light absorbance at a wavelength of 700 nm is 0.13.

By incorporating the wavelength selective absorption filter according to the embodiment of the present invention whose light absorbance is adjusted to the above range into the OLED display device, the original tint of the image of the OLED display device can be maintained at an excellent level, and display performance in which the brightness is higher and the external light reflection is further suppressed can be obtained.

The light absorbance of the wavelength selective absorption filter according to the embodiment of the present invention can be adjusted by a kind and an addition amount (the content in the wavelength selective absorption filter) of the dye.

### <Moisture Content of Wavelength Selective Absorption Filter>

From the viewpoint of the durability, the moisture content of the wavelength selective absorption filter according to the embodiment of the present invention is preferably 0.5% by mass or less, and more preferably 0.3% by mass or less, in conditions of 25° C. and 80% relative humidity, regardless of the film thickness.

In the specification, the moisture content of the wavelength selective absorption filter can be measured by using a sample having a thick film thickness as necessary. The moisture content can be calculated by humidity-conditioning the sample for 24 hours or longer, then measuring a moisture content (g) by the Karl Fischer method with a water measuring instrument and a sample drying apparatus “CA-03” and “VA-05” (both manufactured by Mitsubishi Chemical Corporation), and dividing the moisture content (g) by the sample mass (g, including the moisture content).

### <Glass Transition Temperature (Tg) of Wavelength Selective Absorption Filter>

The glass transition temperature of the wavelength selective absorption filter according to the embodiment of the present invention is preferably 50° C. or higher and 140° C. or lower. More preferably, the glass transition temperature is 60° C. or higher and 130° C. or lower, and more preferably 70° C. or higher and 120° C. or lower. In a case where the glass transition temperature is equal to or higher than the above preferable lower limit value, deterioration in a case of being used at a high temperature can be suppressed, and in a case where the glass transition temperature is equal to or lower than the above preferable upper limit value, it is possible to suppress that the organic solvent used in the coating liquid easily remains in the wavelength selective absorption filter.

The glass transition temperature of the wavelength selective absorption filter according to the embodiment of the present invention can be measured by the following method.

With a differential scanning calorimetry device (X-DSC7000 (manufactured by IT Measurement Control Co., Ltd.)), 20 mg of a wavelength selective absorption filter is placed in a measurement pan, and the temperature of the pan is raised from 30° C. to 120° C. in a nitrogen stream at a speed of 10° C./min, and held for 15 minutes, and then cooled to 30° C. at −20° C./min. Thereafter, the temperature was raised again from 30° C. to 250° C. at a rate of 10° C./min, and the temperature at which the baseline began to deviate from the low temperature side was defined as the glass transition temperature Tg. The glass transition temperature of the wavelength selective absorption filter according to the embodiment of the present invention can be adjusted by mixing two or more kinds of polymers having different glass transition temperatures, or by changing the amount of a small molecule compound such as an antifading agent added.

### <Treatment of Wavelength Selective Absorption Filter>

The wavelength selective absorption filter may be subjected to a hydrophilic treatment by a glow discharge treatment, a corona discharge treatment, an alkali saponification treatment, or the like, where a corona discharge treatment is preferably used. It is also preferable to apply the method disclosed in JP1994-94915A (JP-H06-94915A) and JP1994-118232A (JP-H06-118232A).

If necessary, the obtained film can be subjected to a heat treatment step, a superheated steam contact step, an organic solvent contact step, or the like. In addition, a surface treatment may be suitably performed.

In addition, as a pressure sensitive adhesive layer, a layer consisting of a pressure sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description of the pressure sensitive adhesive layer in the OLED display device described later can be applied.

A predetermined optical film may be attached to the wavelength selective absorption filter according to the embodiment of the present invention.

The predetermined optional optical film is not particularly limited in terms of any of optical properties and materials, and a film containing (or containing as a main component) at least any of a cellulose ester resin, an acrylic resin, a cyclic olefin resin, and a polyethylene terephthalate resin can be preferably used. An optically isotropic film or an optically anisotropic retardation film may be used.

For the above optional optical films, for example, Fujitac TD80UL (manufactured by FUJIFILM Corporation) or the like can be used as a film containing a cellulose ester resin. Regarding the optional optical film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical film containing a (meth)acrylic resin having a glutaric anhydride unit described in JP2009-139754A can be used.

Further, regarding the predetermined optical films, as those containing a cyclic olefin resin, cyclic olefin-based resin film described in a paragraph [0029] and subsequent paragraphs of JP2009-237376A, and cyclic olefin resin film containing an additive reducing Rth described in JP4881827B, JP2008-063536B can be used.

The wavelength selective absorption filter according to the embodiment of the present invention may be provided with a gas barrier layer.

The material forming the gas barrier layer is not particularly limited, and for example, an organic material such as polyvinyl alcohol and polyvinylidene chloride, an organic-inorganic hybrid material such as a sol-gel material, and inorganic materials such as SiO₂, SiOₓ, SiON, SiNₓ, and Al₂O₃ can be exemplified. The gas barrier layer may be a single layer or a multi-layer, and in a case of the multi-layer, a configuration such as an inorganic dielectric multilayer film and a multilayer film in which organic materials and inorganic materials are alternately laminated may be exemplified.

The method for forming the gas barrier layer is not particularly limited. For example, in the case of an organic material, a method by a casing method such as spin coating or slit coating, and a resin gas barrier film can be used as the wavelength selective absorption filter according to the embodiment of the present invention. Examples thereof can include a method of bonding, and in the case of an inorganic material, a plasma enhanced chemical vapor deposition (CVD) method, a sputtering method, a vapor deposition method, and the like are exemplified.

From the viewpoint the decrease in brightness of the light emitted from the OLED can be suppressed, it is preferable that the wavelength selective absorption filter according to the embodiment of the present invention is used in an OLED display device in which a half-width (full width at half maximum) of emitted light having a peak at 500 to 560 nm in a state where the wavelength selective absorption filter is not provided is 45 nm or less, in a case of being applied to the wide color gamut OLED display device.

The half-width (full width at half maximum) of the emitted light having a peak at 500 to 560 nm is preferably 40 nm or less and more preferably 32 nm or less.

In a case where the OLED display device in which a half-width (full width at half maximum) of emitted light having a peak at 500 to 560 nm is 45 nm or less in a state where the wavelength selective absorption filter is not provided is described, the description of the OLED display device below can be applied as it is.

### [OLED Display Device]

The OLED display device according to the embodiment of the present invention includes the wavelength selective absorption filter according to the embodiment of the present invention.

In the OLED display device according to the embodiment of the present invention, as long as the half-width (full width at half maximum) of emitted light having a peak at 500 to 560 nm in a state where the wavelength selective absorption filter is not provided is 45 nm or less (preferably 40 nm or less and more preferably 32 nm or less) and the wavelength selective absorption filter according to the embodiment of the present invention is provided, the configuration of a commonly used OLED display device can be used without particular limitation as the other configurations. The configuration example of the OLED display device according to the embodiment of the present invention is not particularly limited, and examples thereof include a display device including glass, a layer containing a thin film transistor (TFT), an OLED display element, a barrier film, a color filter, glass, a pressure sensitive adhesive layer, the wavelength selective absorption filter according to the embodiment of the present invention, and a surface film, in order from the opposite side to external light.

In the present invention, the half-width of emitted light means a value represented by Relational Expression, that is, a full width at half maximum in a case where only a G (green) pixel is turned on, and a wavelength closest to the peak wavelength λmax on a short wavelength side is defined as λ1 and a wavelength closest to the peak wavelength λmax on a long wavelength side is λ2, among wavelengths having a brightness of ½ of the peak brightness.

(Half-width)=λ2−λ1

The OLED display element has a configuration in which an anode electrode, a light emitting layer, and a cathode electrode are laminated in this order. In addition to the light emitting layer, a hole injection layer, a hole transport layer, an electron transport layer, an electron injection layer, and the like are included between the anode electrode and the cathode electrode. In addition, for example, the description in JP2014-132522A can also be referred to.

Further, as the color filter, in addition to a normal color filter, a color filter in which quantum dots are laminated can also be used.

A resin film can be used instead of the above glass.

By including the wavelength selective absorption filter according to the embodiment of the present invention, the OLED display device according to the embodiment of the present invention can suppress external light reflection by the dye contained in the filter, and can maintain the original tint of the image formed by the light emitted from the light emitting layer (light source) at an excellent level. Further, it is possible to achieve both the suppression of external light reflection and the suppression of brightness decrease at a sufficient level. That is, an antireflection film is usually used as the surface film. However, by adopting the wavelength selective absorption filter according to the embodiment of the present invention, the OLED display device according to the embodiment of the present invention can achieve the excellent effect without using the antireflection film. It should be noted that it does not interfere with the combination use of the antireflection film, as the configuration of the OLED display device according to the embodiment of the present invention, within the range not impairing the effects of the present invention.

A method of forming a color image of an OLED that can be applied to the OLED display device according to the embodiment of the present invention is not particularly limited except that the half-width of G (green) is 45 nm or less (preferably 40 nm or less and more preferably 32 nm or less), and any of a three-color paint scheme of R (red), G (green), and B (blue), a color conversion scheme using quantum dots (QD), and a color filter scheme can be used, and the QD color conversion scheme can be suitably used from the viewpoint that the half-width of G (green) is small, specifically, 40 nm or less, and can be further 32 nm or less, and the combined use scheme of QD color conversion and a color filter can be particularly suitably used. Therefore, as the light source of the OLED display device according to the embodiment of the present invention, each light emitting layer corresponding to the above image forming method can be applied.

For example, in a case where a display element in which quantum dots (QDs) and an OLED are combined is used as the OLED display element, which is referred to as a QD-OLED or the like, it is possible to realize an OLED display device (a wide color gamut OLED display device) in which the half-width of emitted light having a peak at 500 to 560 nm is narrowed to 45 nm or less (preferably 40 nm or less and more preferably 32 nm or less), the color gamut is high, and the color gamut is wider. Examples of the specific configuration include a structure in which a blue OLED is used as a light emitting source and red and green are colored by red and green quantum dots and a color filter, as described in FIG. 2 which will be described later. With regard to the QD-OLED, for example, the description in JP2022-78975A can be referred to except that the QD-OLED has a peak of emitted light having a half-width of 45 nm or less at 500 to 560 nm, and the description in JP2022-78975A can be applied as it is.

### <Pressure Sensitive Adhesive Layer>

In the OLED display device according to the embodiment of the present invention, it is preferable that the wavelength selective absorption filter according to the embodiment of the present invention is bonded to glass via a pressure sensitive adhesive layer.

For the pressure sensitive adhesive layer, the descriptions related to the pressure sensitive adhesive layer and the forming method in the OLED display device, which are described in paragraphs [0296] to [0347] of WO2021/014973A, can be applied as they are.

### <Base Material>

In the OLED display device according to the embodiment of the present invention, it is preferable that the wavelength selective absorption filter according to the embodiment of the present invention is bonded to glass via a pressure sensitive adhesive layer.

The method for forming the pressure sensitive adhesive layer is not particularly limited, and for example, a method of applying the pressure sensitive adhesive composition to the wavelength selective absorption filter according to the embodiment of the present invention by a usual means such as a bar coater, drying, and curing the pressure sensitive adhesive composition; a method of applying the pressure sensitive adhesive composition first to the surface of a peelable base material, and drying the composition, and then transferring the pressure sensitive adhesive layer using the peelable base material to the wavelength selective absorption filter according to the embodiment of the present invention and then aging and curing the composition is used.

The peelable base material is not particularly limited, and a predetermined peelable base material can be used. For example, the release film in the manufacturing method of the wavelength selective absorption filter according to the embodiment of the present invention described above is exemplified.

In addition, the conditions of application, drying, aging, and curing can be appropriately adjusted based on a conventional method.

### EXAMPLES

Hereinafter, the present invention will be described in more detail based on Examples. The materials, amount of use, ratio, details of the treatment, procedures of the treatment, and the like shown in the following examples can be appropriately changed without departing from the spirit of the present invention. Therefore, it is to be understood that the scope of the present invention is not limited to the specific examples shown below.

In the following examples, “parts” and “%” representing the composition are based on mass unless otherwise specified. Further, λₘₐₓ means the maximal absorption wavelength showing the maximum light absorbance.

### [Preparation of Wavelength Selective Absorption Filter]

The materials used to prepare the wavelength selective absorption filter are shown below.

### <Matrix Resin>

### (Resin 10)

Arton RX4500 (product name, manufactured by JSR Corporation, a norbornene-based polymer, Tg: 132° C.), which is a cyclic polyolefin resin, was used as a resin 10.

### (Peelability Control Resin Component 3)

TUFTAK M1943 (product name, manufactured by Asahi Kasei Corporation, hydrogenated styrene-based thermoplastic elastomer (SEBS))

### <Dye>

The following E-14 (λₘₐₓ=430 nm) was used as the dye A, the following 7-23 (λₘₐₓ=505 nm) was used as the dye B, the following C-73 (λₘₐₓ=590 nm) was used as the dye C, and the following F-35 (λₘₐₓ=700 nm) was used as the dye D, respectively.

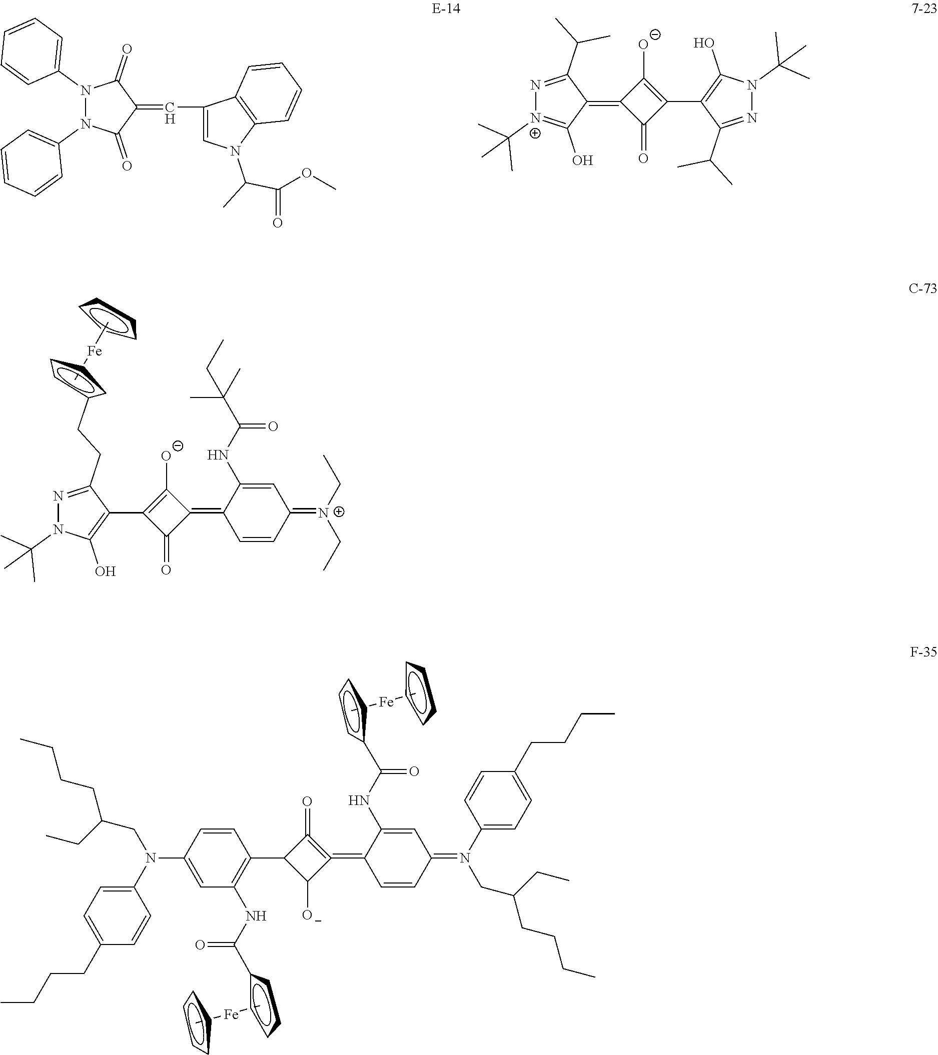

In addition, λₘₐₓ described in the above-mentioned dye section means the maximal absorption wavelength showing the maximum light absorbance measured under the following conditions. That is, the above dye was dissolved in chloroform to prepare a measurement solution having a concentration of 1×10⁻⁶ mol/L. For the measurement solution, the maximal absorption wavelength λₘₐₓ at 23° C. was measured using a cell having an optical path length of 10 mm and a spectrophotometer UV-1800PC (manufactured by Shimadzu Corporation).

### <Additives>

### (Association Inhibitor)

The following compounds were used as an association inhibitor 303.

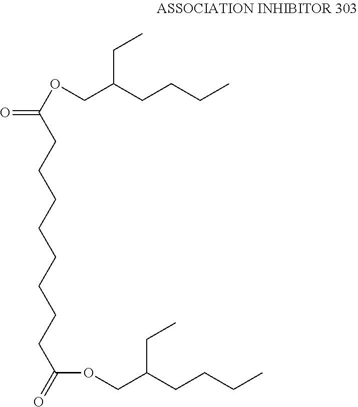 [SMILES: CCCCC(CC)COC(=O)CCCCCCCCC(=O)OCC(CC)CCCC]

### (Base Material 1)

A cellulose acylate film (manufactured by FUJIFILM Corporation, product name: ZRD40SL) was used as a base material 1.

### (1) Preparation of Wavelength Selective Absorption Layer Forming Liquid A

Each component was mixed according to the composition shown below to prepare a wavelength selective absorption layer forming liquid A.

Composition of wavelength selective absorption layer forming liquid A

| | |
|---|---|
| Resin 10 | 87.6 parts by mass |
| Peelability control resin component 3 | 3.4 parts by mass |
| Leveling agent: MEGAFACE F-554 (product | |
| name, manufactured by DIC Corporation, | |
| polymer) | 0.16 parts by mass |
| Dye E-14 | 0.80 parts by mass |
| Dye 7-23 | 0.49 parts by mass |
| Dye C-73 | 2.77 parts by mass |
| Dye F-35 | 0.67 parts by mass |
| Association inhibitor 303 | 4.10 parts by mass |
| Cyclohexane (solvent) | 1018.3 parts by mass |
| Ethyl acetate (solvent) | 548.3 parts by mass |

Subsequently, the obtained wavelength selective absorption layer forming liquid A was filtered using a filter paper (#63, manufactured by Toyo Filter Paper Co., Ltd.) having an absolute filtration precision of 10 μm, and further filtered using a metal sintered filter (FH025, manufactured by Pall) with an absolute filtration precision of 2.5 μm.

### (2) Production of Base Material-Attached Wavelength Selective Absorption Filter No. 1

The wavelength selective absorption layer forming liquid A after the filtration treatment was applied onto the base material 1 by using a bar coater so that the film thickness after drying was 1.2 μm, and dried at 120° C. to produce a base material-attached wavelength selective absorption filter No. 1.

### (3) Production of Base Material-Attached Wavelength Selective Absorption Filter Nos. 2 to 6 and C1 to C3

The base material-attached wavelength selective absorption filters Nos. 2 to 6 and C1 to C3 were prepared in the same manner as in the production of the base material-attached wavelength selective absorption filter No. 1, except that the formulation amount of the dye was changed to the contents shown in the following Table 1. The formulation amount of the peelability control resin component 3, the leveling agent, and the association inhibitor 303 in the base material-attached wavelength selective absorption filter No. 1 was fixed, and then the formulation amount of the resin was changed in accordance with the change in the formulation amount of the dye to adjust the mass of the filter as a whole to be unchanged in mass.

Table 1 below summarizes the configuration of each base material-attached wavelength selective absorption filter. The base material-attached wavelength selective absorption filters No. 1 to 6 are the base material-attached wavelength selective absorption filters according to the embodiment of the present invention, the base material-attached wavelength selective absorption filters No. C1 and C2 are comparative base material-attached wavelength selective absorption filters, and the base material-attached wavelength selective absorption filter No. C3 is a reference base material-attached wavelength selective absorption filter.

### <Maximal Absorption Value of Wavelength Selective Absorption Filter>

Using a UV3150 spectrophotometer (product name) manufactured by Shimadzu Corporation, the light absorbance of a base material-attached wavelength selective absorption filter in the wavelength range of 380 nm to 800 nm was measured every 1 nm. A light absorbance difference between a light absorbance Abₓ (λ) at each wavelength λ nm of the base material-attached wavelength selective absorption filter and Ab₀(λ) of the base material-attached wavelength selective absorption filter (that is, the wavelength selective absorption filter No. C3) that does not contain dye, which is Abₓ (λ)−Ab₀(λ), was calculated, and the maximum value of the light absorbance difference was defined as the maximal absorption value.

In the wavelength selective absorption filter, λₘₐₓ represented by each of dyes was 428 nm for the dye E-14, 504 nm for the dye 7-23, 591 nm for the dye C-73, and 700 nm for the dye F-35.

### <Simulation of Relative Brightness, Reflectance, and Reflected Tint>

The OLED display device described in (1) below comprising the wavelength selective absorption filter prepared above, was subjected to a simulation of external light reflection, and the reflectivity and the reflected tint (x and y) were calculated as described in (3) below, and the relative brightness was calculated as described in (4) below. Table 2 below shows the combination of the emitted light spectrum used in the simulation and the wavelength selective absorption filter, and the evaluation results according to the suppression of external light reflection, the reflected tint, and the suppression of the decrease in brightness.

The base material-attached wavelength selective absorption filter is applied as a wavelength selective absorption filter from which the base material is peeled off.

### (1) Configuration of OLED Display Device

As the OLED display device for performing the simulation, a device for displaying an image by a color filter including a blue OLED element and quantum dots (QD) shown in FIG. 2 was assumed.

That is, an OLED display device 1 shown in FIG. 2 comprises a blue OLED element, an RG selective reflective layer 21, a color filter (CF) including quantum dots (QD), a black matrix 71, and a wavelength selective absorption filter 82 prepared in the above, on a TFT substrate in order. The wavelength selective absorption filter 82 is located on the external light side (visual recognition side).

The TFT substrate has a configuration in which a TFT 12 is provided on a substrate 11. The blue OLED element has a configuration in which an anode 13, a blue OLED 14, and a cathode 15 are laminated from the TFT substrate side. A barrier film 16 is arranged between the blue OLED element and the RG selective reflective layer 21.

A color filter containing quantum dots includes quantum dots as red and green light emitting parts. The color filter corresponding to red has a configuration in which a layer 31 containing the red quantum dots and a light diffusing body, a B selective reflective layer 51, and red color filter 32 are arranged in this order on the RG selective reflective layer 21. The color filter corresponding to green has a configuration in which a layer 41 containing a green quantum dot and a light diffusing body, the B selective reflective layer 51, and a green color filter 42 are arranged in this order on the RG selective reflective layer 21. The layer 31 containing the red quantum dots and the light diffusing body is a color conversion unit that converts light in the blue wavelength range into light in the red wavelength range, and the layer 41 containing the green quantum dots and the light diffusing body is a color conversion unit that converts light in the wavelength range of blue into light in the green wavelength range. The color filter corresponding to blue has a configuration in which a blue color filter 62 is arranged on the RG selective reflective layer 21.

A glass 81 is provided between the color filter and the black matrix 71 containing the quantum dots and the wavelength selective absorption filter 82, and a low reflection surface film 83 is provided on the wavelength selective absorption filter 82.

### (2) Simulation Conditions

In the OLED display device 1 shown in FIG. 2, in the simulation of the reflectivity and the reflected tint according to the irradiation with external light AR, for the reflectivity and the reflection spectrum when the wavelength selective absorption filter was not used, values of carbon black were used.

In the above, the reflection spectrum was measured using a UV3150 spectrophotometer (product name) manufactured by Shimadzu Corporation.

### (3) Calculation of Reflectance and Reflected Tint

The reflectivity and the reflected tint were calculated from the transmission spectrum of the wavelength selective absorption filter measured using the reflection spectrum and a UV3150 spectrophotometer (product name) manufactured by Shimadzu Corporation.

Specifically, it is as follows.

The reflection spectrum of the carbon black was defined as R_{CB}, the transmission spectrum of the wavelength selective absorption filter was defined as T_{dye}, and the reflection spectrum was calculated according to the following expression.

Reflection spectrum=R_{CB}×(T_{dye})²

Based on the reflection spectrum calculated above, the reflectance (visual sensitivity correction) and the reflected tint (x and y) were calculated.

### (4) Calculation of Relative Brightness

The relative brightness in a case where the wavelength selective absorption filter produced above was used was calculated as follows.

As the emitted light spectrum, each of a white display spectrum of RS65-B2 (quantum dot type liquid crystal TV, product name) manufactured by Vizio, Inc.: S(λ)_{A} (half-width of emitted light spectrum at wavelength of 500 to 560 nm: 30 nm), a white display spectrum of XRJ-55A90J (OLED TV, product name) manufactured by Sony Corporation: S(λ)_{B} (half-width of emitted light spectrum at wavelength of 500 to 560 nm: 54 nm), and a backlight spectrum of 55″ Q7F (quantum dot type liquid crystal TV, product name) manufactured by Samsung Electronics Co., Ltd.: S(λ)_{C} (half-width of emitted light spectrum at wavelength of 500 to 560 nm: 39 nm) was used. Further, the transmission spectrum of the wavelength selective absorption filter was defined as T(λ).

The brightness in a case where the wavelength selective absorption filter was not used was calculated by performing visual sensitivity correction on spectra S(λ)_{A}, S(λ)_{B}, and S(λ)_{C}, and each of these brightnesses was set to 100. Each of the brightness of S(λ)_{A}×T(λ), the brightness of S(λ)_{B}×T(λ), and the brightness of S(λ)_{C}×T(λ) in a case of using the wavelength selective absorption filter was calculated as the relative brightness with respect to the brightness in a case of not using the wavelength selective absorption filter.

### <Evaluation of Suppressing Decrease in Brightness>

The relative brightness values obtained in the simulation were applied to the following standards, so that suppression of the decrease in brightness was evaluated.

### —Evaluation Standards—

A: 90<relative brightness ≤100
B: 80<relative brightness ≤90
C: 70<relative brightness ≤80
D: 0≤relative brightness ≤70

### <Evaluation of Suppressing External Light Reflection>

Using the reflectance value obtained in the simulation, the reflectance reduction rate was calculated by the following expression and was applied to the following standards, and the suppression of external light reflection was evaluated.

Reflectance reduction rate=(R0−R1)/R0×100%
R1: Reflectance in a case where using a wavelength selective absorption filter containing a dye
R0: reflectivity in a case where a wavelength selective absorption filter No. C3 not containing a dye was used

### —Evaluation Standards—

A: 50%<Reflectance reduction rate ≤80%
B: 20%<Reflectance reduction rate ≤50%
C: 0≤reflectance reduction rate ≤20%

### <Evaluation of External Light Reflected Tint>

The values of x and y obtained in the simulation were applied to the following standards, and the external light reflected tint was evaluated. The evaluation standard “A” corresponds to the coordinates of the xy chromaticity diagram in which the color temperature of the white display tint is 8000 to 12000 K, the evaluation standard “B” corresponds to the coordinates of the xy chromaticity diagram in which the color temperature of the white display tint is 6500 K or higher and lower than 8000 K, and the evaluation standard “C” corresponds to the coordinates of the xy chromaticity diagram in which the color temperature of the white display tint is lower than 6500 K or exceeds 12000 K. Therefore, as long as the evaluation is “B” or preferably “A”, the reflected tint of the wavelength selective absorption filter and the white display tint of the emitted light are close to each other, and the difference in tints between the display light and the reflected light of the display image is not easily visually recognized, which is preferable.

### —Evaluation Standards—

A: (0.269, 0.280)≤(x, y)≤(0.295, 0.305)
B: (0.269, 0.280)≤(x, y)≤(0.313, 0.329) (However, x, y corresponding to A are excluded)
C: (x,y)<(0.269,0.280), or (x,y)>(0.313,0.329)

TABLE 1

| Wavelength | Formulation | | | | Ab | Ab | Ab | Ab | Light | | | |
|---|---|---|---|---|---|---|---|---|---|---|---|---|
| selective | amount of dye | | | | (430)/ | (500)/ | (430)/ | (700)/ | absorbance | | | |
| absorption | Dye | Dye | Dye | Dye | Ab | Ab | Ab | Ab | Ab | Ab | Ab | Ab |
| filter No. | A | B | C | D | (600) | (600) | (700) | (600) | (430) | (500) | (600) | (700) |
| 1 | 0.80 | 0.49 | 2.77 | 0.67 | 0.14 | 0.22 | 0.62 | 0.22 | 0.08 | 0.13 | 0.60 | 0.13 |
| 2 | — | 1.00 | 2.00 | 1.50 | 0.08 | 0.56 | 0.11 | 0.68 | 0.03 | 0.24 | 0.44 | 0.30 |
| 3 | 2.00 | 0.85 | 2.50 | 1.00 | 0.31 | 0.39 | 0.85 | 0.36 | 0.17 | 0.21 | 0.54 | 0.20 |
| 4 | 1.50 | 0.70 | 2.50 | 2.00 | 0.25 | 0.33 | 0.35 | 0.72 | 0.14 | 0.18 | 0.55 | 0.40 |
| 5 | 3.00 | 1.50 | 3.00 | 0.50 | 0.37 | 0.56 | 2.47 | 0.15 | 0.24 | 0.36 | 0.65 | 0.10 |
| 6 | 1.40 | 0.95 | 1.80 | 2.10 | 0.33 | 0.58 | 0.32 | 1.04 | 0.13 | 0.23 | 0.40 | 0.42 |
| C1 | 4.00 | 1.80 | 1.20 | 3.00 | 1.14 | 1.53 | 0.54 | 2.12 | 0.32 | 0.43 | 0.28 | 0.60 |
| C2 | 4.00 | 0.95 | 2.00 | 0.50 | 0.69 | 0.54 | 3.03 | 0.23 | 0.30 | 0.23 | 0.43 | 0.10 |
| C3 | — | — | — | — | — | — | — | — | 0.00 | 0.00 | 0.00 | 0.00 |

TABLE 2

| | | Half-width | | Result | | |
|---|---|---|---|---|---|---|
| | | of emitted | Wavelength | Suppression | | |
| | Emitted | light having | selective | of external | | Suppression |
| | light | peak at 500 | absorption | light | Reflected | of decrease |
| | spectrum | to 560 nm | filter No. | reflection | tint | in brightness |
| Example 1 | S (λ)_{A} | 30 nm | 1 | A | A | B |
| Example 2 | S (λ)_{A} | 30 nm | 2 | B | B | B |
| Example 3 | S (λ)_{A} | 30 nm | 3 | A | B | B |
| Example 4 | S (λ)_{A} | 30 nm | 4 | A | A | B |
| Example 5 | S (λ)_{A} | 30 nm | 5 | A | B | C |
| Example 6 | S (λ)_{A} | 30 nm | 6 | A | B | B |
| Reference | S (λ)_{B} | 54 nm | 1 | A | A | D |
| Example 1 | | | | | | |
| Example 7 | S (λ)_{C} | 39 nm | 1 | A | A | C |
| Comparative | S (λ)_{A} | 30 nm | C1 | B | C | C |
| Example 1 | | | | | | |
| Comparative | S (λ)_{A} | 30 nm | C2 | B | C | B |
| Example 2 | | | | | | |
| Reference | S (λ)_{A} | 30 nm | C3 | C | C | A |
| Example 2 | | | | | | |

### (Note in Table 1)

Formulation amount of dye: means the formulation amount of dye in 100 parts by mass of the filter, and the unit is parts by mass. The notation of “−” in the column of the dye indicates that the corresponding dye is not contained.

Light absorbance: it indicates light absorbance at 430 nm, 500 nm, 600 nm, and 700 nm among light absorbances Abₓ(λ) at the wavelength of λ nm of the base material-attached wavelength selective absorption filter measured as described above.

Ab (430)/Ab (600), Ab (500)/Ab (600), Ab (430)/Ab (700), and Ab (700)/Ab (600) indicate the ratio of the light absorbance calculated using Ab (430), Ab (500), Ab (600), and Ab (700) described in the column of the light absorbance, respectively.

The notation of “-” in the column of the dye of No. C3 and the ratio of the respective light absorbances refers to the value is not described because No. C3 is a base material-attached wavelength selective absorption filter that does not contain a dye and corresponds to a reference filter of each wavelength selective absorption filter.

### (Note in Table 2)

S(λ)_{A}, S(λ)_{B}, and S(λ)_{C}: respectively correspond to the emitted light spectra S(λ)_{A}, S(λ)_{B}, and S(λ)_{C}.

Wavelength selective absorption filters Nos. 1 to 6 and C1 to C3: corresponding to wavelength selective absorption filters Nos. 1 to 6 and C1 to C3 shown in Table 1, respectively.

From the results in Table 1 and Table 2, the following points can be seen.

As shown in Reference Example 2, in the reference wavelength selective absorption filter No. C3 not containing a dye, suppression of external light reflection and suppression of influence on the original tint of the display image were insufficient. In addition, the comparative wavelength selective absorption filter No. C1 used in Comparative Example 1 does not satisfy Relational Expression (I) according to the embodiment of the present invention, and the comparative wavelength selective absorption filter No. C2 used in Comparative Example 2 does not satisfy Relational Expression (II) according to the embodiment of the present invention. In these comparative wavelength selective absorption filters Nos. C1 and C2, the reflected tint and the white display tint of the emitted light were separated from each other, and the influence on the original tint of the display image was not suppressed.

On the other hand, as shown in Examples 1 to 7 and Reference Example 1, the wavelength selective absorption filters Nos. 1 to 6 according to the embodiment of the present invention were excellent in suppressing external light reflection, and the reflected tint was close to the white display tint of the emitted light, and thus the influence on the original tint of the display image was suppressed. In addition, as shown in Examples 1 to 7, in a case where the wavelength selective absorption filter according to the embodiment of the present invention was applied to a display device comprising a QDOLED having a narrow half-width of a peak of emitted light at a wavelength of 500 to 560 nm, of 30 nm or 39 nm, a decrease in brightness due to the provision of the wavelength selective absorption filter was suppressed. As shown in Examples 1, 7, and Reference Example 1, it can be seen that the wavelength selective absorption filter according to the embodiment of the present invention is applied to a display device comprising a QDOLED having a narrow half-width of a peak of emitted light at a wavelength of 500 to 560 nm, whereby a decrease in brightness due to the provision of the wavelength selective absorption filter is further suppressed.

Although the present invention has been described with reference to the embodiments, it is our intention that the present invention not be limited by any of the details of the description, unless otherwise specified, but rather be construed broadly within its spirit and scope as set out in the accompanying claims.

### EXPLANATION OF REFERENCES

1: OLED display device
11: substrate
12: thin film transistor (TFT)
13: anode
14: blue OLED (BOLED)
15: cathode
16: barrier film
21: red-green selective reflective layer (RG selective reflective layer)
31: layer containing red quantum dots (red QD) and light diffusing body
32: red color filter
41: layer containing green quantum dots (green QD) and light diffusing body
42: green color filter
51: blue selective reflective layer (B selective reflective layer)
62: blue color filter
71: black matrix
81: glass
82: wavelength selective absorption filter
83: surface film
AR: external light
BMᵢₙ: incidence of external light on black matrix
Rᵢₙ: incidence of external light on red pixel
Gᵢₙ: incidence of external light on green pixel
Bᵢₙ: incidence of external light on blue pixel
BM_{ref}: reflection of external light in black matrix
R_{ref}: reflection of external light in red pixel
G_{ref}: reflection of external light in green pixel
B_{ref}: reflection of external light in blue pixel

What is claimed is:

1. A wavelength selective absorption filter comprising:
a resin; and
the following dyes B, C, and D having a main absorption wavelength range in different wavelength regions,
wherein a light absorbance Ab (λ) of the wavelength selective absorption filter at a wavelength of λ nm satisfies Relational Expressions (I) and (II),
dye B: a dye having a main absorption wavelength range at a wavelength of 480 to 520 nm in the wavelength selective absorption filter,
dye C: a dye having a main absorption wavelength range at a wavelength of 580 to 620 nm in the wavelength selective absorption filter,
dye D: a dye having a main absorption wavelength range at a wavelength of 680 to 780 nm in the wavelength selective absorption filter,
Ab(500)/Ab(600)<0.7, and Relational Expression (I)
Ab(430)/Ab(700)<3.0. Relational Expression (II)

2. The wavelength selective absorption filter according to claim 1, further comprising:
the following dye A,
dye A: a dye having a main absorption wavelength range at a wavelength of 390 to 435 nm in the wavelength selective absorption filter.

3. The wavelength selective absorption filter according to claim 1,
wherein Relational Expression (II-a) is satisfied,
Ab(430)/Ab(700)<1.0. Relational Expression (II-a)

4. The wavelength selective absorption filter according to claim 1,
wherein Relational Expressions (III) and (IV) are satisfied,
Ab(430)/Ab(600)<1.0, and Relational Expression (III)
Ab(700)/Ab(600)<2.0. Relational Expression (IV)

5. The wavelength selective absorption filter according to claim 1,
wherein in a case where the wavelength selective absorption filter is not provided, the wavelength selective absorption filter is used in an organic electroluminescent display device in which a half-width of emitted light having a peak at a wavelength of 500 to 560 nm is 45 nm or less.

6. An organic electroluminescent display device in which in a case where a wavelength selective absorption filter is not provided, a half-width of emitted light having a peak at a wavelength of 500 to 560 nm is 45 nm or less, the organic electroluminescent display device comprising:
the wavelength selective absorption filter according to claim 1.
